(19) United States
(12) Patent Application Publication
(10) Pub. No.: US 2026/0113933 A1
(43) Pub. Date: Apr. 23, 2026

(54) MEMORIES CONTAINING AN ARRAY OF READ-ONLY MEMORY CELLS AND METHODS OF THEIR FABRICATION AND OPERATION

(71) Applicant: MICRON TECHNOLOGY, INC., Boise, ID (US)

(72) Inventors: Martin W. Popp, Boise, ID (US); Homer Monte Manning, Eagle, ID (US); Vladimir Mikhalev, Boise, ID (US)

(73) Assignee: MICRON TECHNOLOGY, INC., Boise, ID (US)

(21) Appl. No.: 19/352,944

(22) Filed: Oct. 8, 2025

Related U.S. Application Data
(60) Provisional application No. 63/709,623, filed on Oct. 21, 2024.

(51) Int. Cl. H10B 20/00; G11C 17/06

(52) U.S. Cl. CPC H10B 20/27; G11C 17/06

(57) ABSTRACT

Memories might include a plurality of access lines extending in a first direction and having a first conductivity type, a plurality of conductive regions extending in the first direction and having a second conductivity type, a dielectric overlying the plurality of conductive regions, a plurality of data lines extending in a second direction and overlying the dielectric, and a plurality of contacts, wherein each contact of the plurality of contacts is formed in the dielectric at an intersection of a respective data line and a respective conductive region to connect its respective data line to its respective conductive region, and wherein a number of contacts is less than a number of data lines of the plurality of data lines times a number of access lines of the plurality of access lines.

This application claims the benefit of U.S. Provisional Application No. 63/709,623, filed on Oct. 21, 2024, hereby incorporated herein in its entirety by reference.

### TECHNICAL FIELD

The present disclosure relates generally to integrated circuits and methods of their formation, and, in particular, in one or more embodiments, the present disclosure relates to memories containing an array of read-only memory cells and methods of their fabrication and operation.

### BACKGROUND

Integrated circuit devices traverse a broad range of electronic devices. One particular type includes memory devices, often referred to simply as memory. Memory devices are typically provided as internal, semiconductor, integrated circuit devices in computers or other electronic devices. There are many different types of memory including random-access memory (RAM), read-only memory (ROM), dynamic random access memory (DRAM), synchronous dynamic random access memory (SDRAM), and flash memory.

Flash memory has developed into a popular source of non-volatile memory for a wide range of electronic applications. Flash memory typically use a one-transistor memory cell that allows for high memory densities, high reliability, and low power consumption. Changes in threshold voltage (Vt) of the memory cells, through programming (which is often referred to as writing) of charge storage nodes (e.g., floating gates or charge traps) or other physical phenomena (e.g., phase change or polarization), determine the data state (e.g., data value) of each memory cell. Common uses for flash memory and other non-volatile memory include personal computers, personal digital assistants (PDAs), digital cameras, digital media players, digital recorders, games, appliances, vehicles, wireless devices, mobile telephones, and removable memory modules, and the uses for non-volatile memory continue to expand.

A NAND flash memory is a common type of flash memory device, so called for the logical form in which the basic memory cell configuration is arranged. Typically, the array of memory cells for NAND flash memory is arranged such that the control gate of each memory cell of a row of the array might be connected together to form an access line, such as a word line. Columns of the array include strings (often termed NAND strings) of memory cells connected together in series between a pair of select gates, e.g., a source select transistor and a drain select transistor. Each source select transistor might be connected to a common source, while each drain select transistor might be connected to a data line, such as column bit line. Variations using more than one select gate between a string of memory cells and the common source, and/or between the string of memory cells and the data line, are known.

Non-volatile memory devices might include a controller (e.g., an internal controller) to manage access operations to an array of non-volatile memory cells. To manage memory array access operations, a non-volatile memory device controller might execute instructions stored in a read-only memory located in the non-volatile memory device. In some cases, such instructions might be programmed into a read-only memory during fabrication.

### BRIEF DESCRIPTION OF THE DRAWINGS

FIG. 1 is a simplified block diagram of a memory in communication with a processor as part of an electronic system, according to an embodiment.

FIGS. 2A-2B are schematics of a portion of an array of memory cells in accordance with an embodiment.

FIG. 3 is a block schematic of a read-only memory in accordance with an embodiment.

FIGS. 4A-4B are block schematics of latches as a pair of cross-coupled inverters that could be used with embodiments.

FIG. 5 is a block schematic of a portion of an array of read-only memory cells in accordance with an embodiment storing data of Table 1.

FIG. 6 is a plan view of a portion of an array of read-only memory cells in accordance with an embodiment storing data of Table 1 for use in describing its fabrication.

FIGS. 7A-7J are cross-sectional views of the portion of the array of read-only memory cells of FIG. 6 during various stages of fabrication.

FIGS. 8A-8J are cross-sectional views of the portion of the array of read-only memory cells of FIG. 6, orthogonal to the views of FIGS. 7A-7J, during various stages of fabrication.

FIGS. 9A-9J are cross-sectional views of CMOS circuitry during various stages of fabrication concurrent with fabrication of the array of read-only memory cells in accordance with embodiments.

FIGS. 10A-10D are cross-sectional views of the portion of the array of read-only memory cells of FIG. 6, corresponding to a same cross-section as the views of FIGS. 7A-7J, during various stages of fabrication in accordance with another embodiment.

FIG. 11A is a cross-sectional view of the portion of the array of read-only memory cells of FIG. 6, corresponding to a same cross-section as the views of FIGS. 7A-7J, depicting alternate isolation structures in accordance with an embodiment.

FIG. 11B is a cross-sectional view of the portion of the array of read-only memory cells of FIG. 6, corresponding to a same cross-section as the views of FIGS. 10A-10D, depicting alternate isolation structures in accordance with another embodiment.

FIGS. 12A-12B are cross-sectional views showing possible connection paths to access lines of an array of read-only memory cells in accordance with embodiments.

FIG. 13 is a flowchart of a method of operating a read-only memory in accordance with an embodiment.

### DETAILED DESCRIPTION

In the following detailed description, reference is made to the accompanying drawings that form a part hereof, and in which is shown, by way of illustration, specific embodiments. In the drawings, like reference numerals describe substantially similar components throughout the several views. Other embodiments might be utilized and structural, logical and electrical changes might be made without departing from the scope of the present disclosure. The following detailed description is, therefore, not to be taken in a limiting sense.

The term “semiconductor” used herein can refer to, for example, a layer of material, a wafer, or a substrate, and includes any base semiconductor structure. “Semiconductor” is to be understood as including silicon on sapphire (SOS) technology, silicon on insulator (SOI) technology, thin film transistor (TFT) technology, doped and undoped semiconductors, epitaxial layers of a silicon supported by a base semiconductor structure, as well as other semiconductor structures well known to one skilled in the art. Furthermore, when reference is made to a semiconductor in the following description, previous process steps may have been utilized to form regions/junctions in the base semiconductor structure, and the term semiconductor can include the underlying layers containing such regions/junctions.

The term “conductive” as used herein, as well as its various related forms, e.g., conduct, conductively, conducting, conduction, conductivity, etc., refers to electrically conductive unless otherwise apparent from the context. Similarly, the term “connecting” as used herein, as well as its various related forms, e.g., connect, connected, connection, etc., refers to electrically connecting by a conductive path unless otherwise apparent from the context.

As used herein, multiple acts being performed concurrently will mean that each of these acts is performed for a respective time period, and each of these respective time periods overlaps, in part or in whole, with each of the remaining respective time periods. In other words, portions of each of those acts are simultaneously performed for at least some period of time.

Unless otherwise defined, directional references such as upper, top, lower, bottom, side, left, right, parallel, orthogonal, etc. as used in the description of the figures refers to such directions relative to the orientation of the figure itself.

It is recognized herein that even where values might be intended to be equal, variabilities and accuracies of industrial processing and operation might lead to differences from their intended values. These variabilities and accuracies will generally be dependent upon the technology utilized in fabrication and operation of the integrated circuit device. As such, if values are intended to be equal, those values are deemed to be equal regardless of their resulting values.

Various embodiments described herein might facilitate a reduction in size, e.g., area or footprint, of an array of read-only memory cells. Read-only memory cells in accordance with embodiments might be “programmed” at the time of fabrication. That is, their respective stored data values might be defined at the time of fabrication. Achievable cell size is believed to be on the order of 0.044 μm² under current fabrication norms. As will be discussed in more detail below, various embodiments might further facilitate reductions in fabrication time and increases in yield.

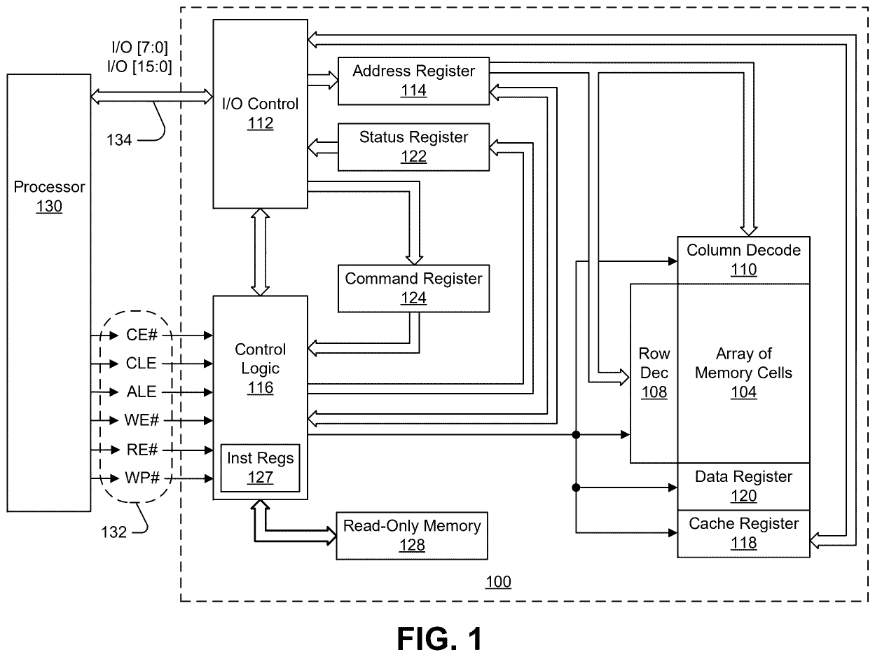

FIG. 1 is a simplified block diagram of a first apparatus, in the form of a memory (e.g., memory device) 100, in communication with a second apparatus, in the form of a processor 130, as part of a third apparatus, in the form of an electronic system, according to an embodiment. Some examples of electronic systems include personal computers, personal digital assistants (PDAs), digital cameras, digital media players, digital recorders, games, appliances, vehicles, wireless devices, mobile telephones and the like. The processor 130, e.g., a controller external to the memory device 100, might be a memory controller or other external host device.

Memory device 100 includes an array of memory cells 104 that might be logically arranged in rows and columns. Memory cells of a logical row are typically connected to the same access line (commonly referred to as a word line) while memory cells of a logical column are typically selectively connected to the same data line (commonly referred to as a bit line). A single access line might be associated with more than one logical row of memory cells and a single data line might be associated with more than one logical column. Memory cells (not shown in FIG. 1) of at least a portion of array of memory cells 104 are capable of being programmed to one of at least two different data states.

A row decode circuitry 108 and a column decode circuitry 110 are provided to decode address signals. Address signals are received and decoded to access the array of memory cells 104. Memory device 100 also includes input/output (I/O) control circuitry 112 to manage input of commands, addresses and data to the memory device 100 as well as output of data and status information from the memory device 100. An address register 114 is in communication with I/O control circuitry 112 and row decode circuitry 108 and column decode circuitry 110 to latch the address signals prior to decoding. A command register 124 is in communication with I/O control circuitry 112 and control logic 116 to latch incoming commands.

A controller (e.g., the control logic 116 internal to the memory device 100) controls access to the array of memory cells 104 in response to the commands from the external processor 130 and might generate status information for the external processor 130, i.e., control logic 116 is configured to perform array operations (e.g., sensing operations [which might include read operations and verify operations], programming operations and/or erase operations) on the array of memory cells 104 in accordance with embodiments. The control logic 116 is in communication with row decode circuitry 108 and column decode circuitry 110 to control the row decode circuitry 108 and column decode circuitry 110 in response to the addresses.

The control logic 116 might include instruction registers 127 which might represent computer-usable memory for storing computer-readable instructions. For some embodiments, the instruction registers 127 might represent firmware. The control logic 116 further might be in communication with read-only memory 128, which might represent computer-usable memory for storing additional computer-readable instructions and other data for use by the control logic 116 during operation. The read-only memory 128 might be readable by the control logic 116 in response to computer-readable instructions stored in the instruction registers 127. The read-only memory 128 might include an array of read-only memory cells, e.g., an array of diodes, in accordance with one or more embodiments. The read-only memory 128 might further be a portion of the control logic 116.

Control logic 116 might also be in communication with a cache register 118. Cache register 118 latches data, either incoming or outgoing, as directed by control logic 116 to temporarily store data while the array of memory cells 104 is busy writing or reading, respectively, other data. During a programming operation (e.g., write operation), data might be passed from the cache register 118 to the data register 120 for transfer to the array of memory cells 104, then new data might be latched in the cache register 118 from the I/O control circuitry 112. During a read operation (e.g., sensing operation), data might be passed from the cache register 118 to the I/O control circuitry 112 for output to the external processor 130, then new data might be passed from the data register 120 to the cache register 118. The cache register 118 and/or the data register 120 might form (e.g., might form a portion of) a page buffer of the memory device 100. A data register 120 might further include sense circuits (not shown in FIG. 1) to sense a data state of a memory cell of the array of memory cells 104, e.g., by sensing a state of a data line connected to that memory cell. A status register 122 might be in communication with I/O control circuitry 112 and control logic 116 to latch the status information for output to the processor 130.

Memory device 100 receives control signals at control logic 116 from processor 130 over a control link 132. The control signals might include a chip enable CE #, a command latch enable CLE, an address latch enable ALE, a write enable WE #, a read enable RE #, and a write protect WP #. Additional or alternative control signals (not shown) might be further received over control link 132 depending upon the nature of the memory device 100. Memory device 100 receives command signals (which represent commands), address signals (which represent addresses), and data signals (which represent data) from processor 130 over a multiplexed input/output (I/O) bus 134 and outputs data to processor 130 over I/O bus 134.

For example, the commands might be received over input/output (I/O) pins [7:0] of I/O bus 134 at I/O control circuitry 112 and might then be written into command register 124. The addresses might be received over input/output (I/O) pins [7:0] of I/O bus 134 at I/O control circuitry 112 and might then be written into address register 114. The data might be received over input/output (I/O) pins [7:0] for an 8-bit device or input/output (I/O) pins [15:0] for a 16-bit device at I/O control circuitry 112 and then might be written into cache register 118. The data might be subsequently written into data register 120 for programming the array of memory cells 104. For another embodiment, cache register 118 might be omitted, and the data might be written directly into data register 120. Data might also be output over input/output (I/O) pins [7:0] for an 8-bit device or input/output (I/O) pins [15:0] for a 16-bit device. Although reference might be made to I/O pins, they might include any conductive nodes providing for electrical connection to the memory device 100 by an external device (e.g., processor 130), such as conductive pads or conductive bumps as are commonly used.

It will be appreciated by those skilled in the art that additional or alternative circuitry and signals can be provided, and that the memory device 100 of FIG. 1 has been simplified. It should be recognized that the functionality of the various block components described with reference to FIG. 1 might not necessarily be segregated to distinct components or component portions of an integrated circuit device. For example, a single component or component portion of an integrated circuit device could be adapted to perform the functionality of more than one block component of FIG. 1. Alternatively, one or more components or component portions of an integrated circuit device could be combined to perform the functionality of a single block component of FIG. 1.

Additionally, while specific I/O pins are described in accordance with popular conventions for receipt and output of the various signals, it is noted that other combinations or numbers of I/O pins (or other I/O node structures) might be used in the various embodiments.

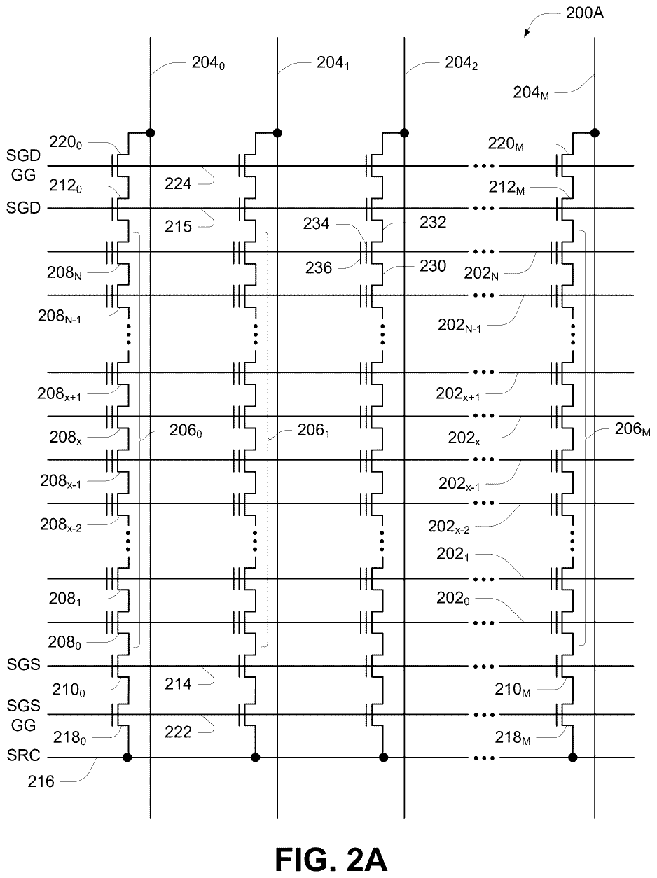

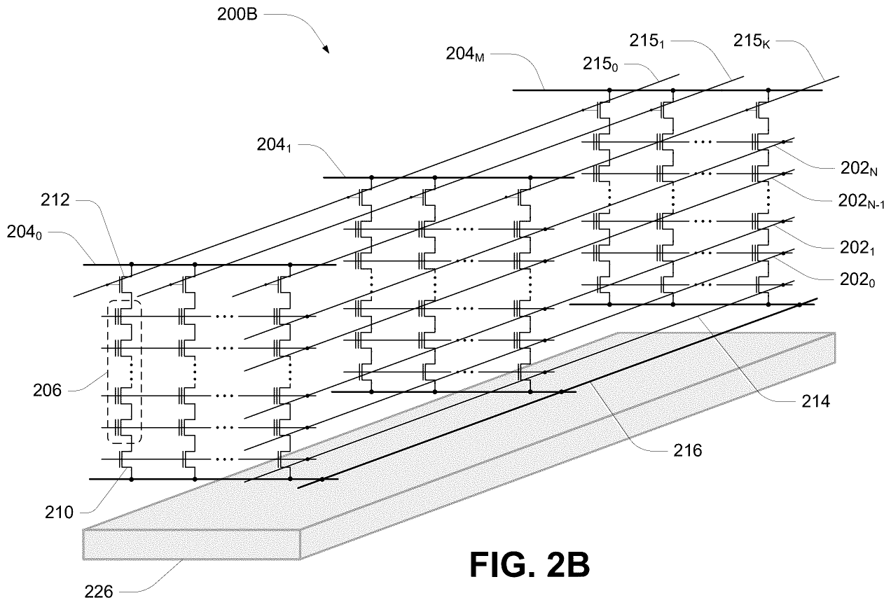

FIG. 2A is a schematic of a portion of an array of memory cells 200A, such as a NAND memory array, as could be used in a memory of the type described with reference to FIG. 1, e.g., as a portion of array of memory cells 104. Memory array 200A includes access lines, such as access lines (e.g., word lines) 202₀ to 202_{N}, and data lines, such as data lines (e.g., bit lines) 204₀ to 204_{M}. The access lines 202 might be connected to global access lines (e.g., global word lines), not shown in FIG. 2A, in a many-to-one relationship. For some embodiments, memory array 200A might be formed over a semiconductor that, for example, might be conductively doped to have a conductivity type, such as a p-type conductivity, e.g., to form a p-well, or an n-type conductivity, e.g., to form an n-well.

Memory array 200A might be arranged in rows (each corresponding to an access line 202) and columns (each corresponding to a data line 204). Each column might include a string of series-connected memory cells (e.g., non-volatile memory cells), such as one of NAND strings 206₀ to 206_{M}. Each NAND string 206 might be connected (e.g., selectively connected) to a common source (SRC) 216 and might include memory cells 208₀ to 208_{N}. The memory cells 208 might represent non-volatile memory cells for storage of data. Some of the memory cells 208 might represent dummy memory cells, e.g., memory cells not intended to store user data. Dummy memory cells are typically not accessible to a user of the memory, and are typically incorporated into the NAND string 206 for operational advantages, as are well understood.

The memory cells 208 of each NAND string 206 might be connected in series between a select gate 210 (e.g., a field-effect transistor), such as one of the select gates 210₀ to 210_{M} (e.g., that might be source select transistors, commonly referred to as select gate source), and a select gate 212 (e.g., a field-effect transistor), such as one of the select gates 212₀ to 212_{M} (e.g., that might be drain select transistors, commonly referred to as select gate drain). Select gates 210₀ to 210_{M} might be commonly connected to a select line 214, such as a source select line (SGS), and select gates 212₀ to 212_{M} might be commonly connected to a select line 215, such as a drain select line (SGD). Although depicted as traditional field-effect transistors, the select gates 210 and 212 might utilize a structure similar to (e.g., the same as) the memory cells 208. The select gates 210 and 212 might represent a plurality of select gates connected in series, with each select gate in series configured to receive a same or independent control signal. A control gate of each select gate 210 might be connected to select line 214. A control gate of each select gate 212 might be connected to select line 215.

The select gates 210 for each NAND string 206 might be connected in series between its memory cells 208 and a GIDL (gate-induced drain leakage) generator gate 218 (e.g., a field-effect transistor), such as one of the GIDL generator (GG) gates 218₀ to 218_{M}. The GG gates 218₀ to 218_{M} might be referred to as source GG gates. The source GG gates 218₀ to 218_{M} might each be connected (e.g., directly connected) to the source 216, and selectively connected to their respective NAND strings 206₀ to 206_{M}. Alternatively, a source select gate 210 and its GG gate 218 might represent a single gate, e.g., connected (e.g., directly connected) to the source 216, and connected (e.g., directly connected) to a respective NAND string 206.

The select gates 212 of each NAND string 206 might be connected in series between its memory cells 208 and a GG gate 220 (e.g., a field-effect transistor), such as one of the GG gates 220₀ to 220_{M}. The GG gates 220₀ to 220_{M} might be referred to as drain GG gates. The drain GG gates 220₀ to 220_{M} might be connected (e.g., directly connected) to their respective data lines 204₀ to 204_{M}, and selectively connected to their respective NAND strings 206₀ to 206_{M}. Alternatively, a drain select gate 212 and its GG gate 220 might represent a single gate, e.g., connected (e.g., directly connected) to a respective data line 204, and connected (e.g., directly connected) to a respective NAND string 206.

GG gates 218₀ to 218_{M} might be commonly connected to a control line 222, such as an SGS_GG control line, and GG gates 220₀ to 220_{M} might be commonly connected to a control line 224, such as an SGD_GG control line. Although depicted as traditional field-effect transistors, the GG gates 218 and 220 might utilize a structure similar to (e.g., the same as) the memory cells 208. The GG gates 218 and 220 might represent a plurality of GG gates connected in series, with each GG gate in series configured to receive a same or independent control signal. In general, the GG gates 218 and 220 might have threshold voltages different than (e.g., lower than) the threshold voltages of the select gates 210 and 212, respectively. Threshold voltages of the source GG gates 218 might be different than (e.g., higher than) threshold voltages of the drain GG gates 220. Threshold voltages of the GG gates 218 and 220 might be of an opposite polarity than, and/or might be lower than, threshold voltages of the select gates 210 and 212, respectively. For example, the select gates 210 and 212 might have positive threshold voltages (e.g., 2V to 4V), while the GG gates 218 and 220 might have negative threshold voltages (e.g., −1V to −4V). The GG gates 218 and 220 might be provided to assist in the generation of GIDL current into a channel of their corresponding NAND string 206 during an erase operation, for example.

A source of each GG gate 218 might be connected to common source 216. The drain of each GG gate 218 might be connected to a select gate 210 of the corresponding NAND string 206. For example, the drain of GG gate 218₀ might be connected to the source of select gate 210₀ of the corresponding NAND string 206₀. Therefore, in cooperation, each select gate 210 and GG gate 218 for a corresponding NAND string 206 might be configured to selectively connect that NAND string 206 to common source 216. A control gate of each GG gate 218 might be connected to control line 222.

The drain of each GG gate 220 might be connected to the data line 204 for the corresponding NAND string 206. For example, the drain of GG gate 220₀ might be connected to the data line 204₀ for the corresponding NAND string 206₀. The source of each GG gate 220 might be connected to a select gate 212 of the corresponding NAND string 206. For example, the source of GG gate 220₀ might be connected to select gate 212₀ of the corresponding NAND string 206₀. Therefore, in cooperation, each select gate 212 and GG gate 220 for a corresponding NAND string 206 might be configured to selectively connect that NAND string 206 to the corresponding data line 204. A control gate of each GG gate 220 might be connected to control line 224.

The memory array in FIG. 2A might be a quasi-two-dimensional memory array and might have a generally planar structure, e.g., where the common source 216, NAND strings 206 and data lines 204 extend in substantially parallel planes. Alternatively, the memory array in FIG. 2A might be a three-dimensional memory array, e.g., where NAND strings 206 might extend substantially perpendicular to a plane containing the common source 216 and to a plane containing the data lines 204 that might be substantially parallel to the plane containing the common source 216.

Typical construction of memory cells 208 includes a data-storage structure 234 (e.g., a floating gate, charge trap, or other structure configured to store charge) that can determine a data state of the memory cell (e.g., through changes in threshold voltage), and a control gate 236, as shown in FIG. 2A. The data-storage structure 234 might include both conductive and dielectric structures while the control gate 236 is generally formed of one or more conductive materials. In some cases, memory cells 208 might further have a defined source/drain (e.g., source) 230 and a defined source/drain (e.g., drain) 232. Memory cells 208 have their control gates 236 connected to (and in some cases form) an access line 202.

A column of the memory cells 208 might be a NAND string 206 or a plurality of NAND strings 206 selectively connected to a given data line 204. A row of the memory cells 208 might be memory cells 208 commonly connected to a given access line 202. A row of memory cells 208 can, but need not, include all memory cells 208 commonly connected to a given access line 202. Rows of memory cells 208 might often be divided into one or more groups of physical pages of memory cells 208, and physical pages of memory cells 208 often include every other memory cell 208 commonly connected to a given access line 202. For example, memory cells 208 commonly connected to access line 202_{N} and selectively connected to even data lines 204 (e.g., data lines 204₀, 204₂, 204₄, etc.) might be one physical page of memory cells 208 (e.g., even memory cells) while memory cells 208 commonly connected to access line 202_{N} and selectively connected to odd data lines 204 (e.g., data lines 204₁, 204₃, 204₅, etc.) might be another physical page of memory cells 208 (e.g., odd memory cells). Although data lines 204₃-204₅ are not explicitly depicted in FIG. 2A, it is apparent from the figure that the data lines 204 of the array of memory cells 200A might be numbered consecutively from data line 204₀ to data line 204_{M}. Other groupings of memory cells 208 commonly connected to a given access line 202 might also define a physical page of memory cells 208. For certain memory devices, all memory cells commonly connected to a given access line might be deemed a physical page of memory cells. The portion of a physical page of memory cells (which, in some embodiments, could still be the entire row) that is read during a single read operation or programmed during a single programming operation (e.g., an upper or lower page of memory cells) might be deemed a logical page of memory cells. A block of memory cells might include those memory cells that are configured to be erased together, such as all memory cells connected to access lines 202₀-202_{N} (e.g., all NAND strings 206 sharing common access lines 202). Unless expressly distinguished, a reference to a page of memory cells herein refers to the memory cells of a logical page of memory cells.

FIG. 2B is another schematic of a portion of an array of memory cells 200B as could be used in a memory of the type described with reference to FIG. 1, e.g., as a portion of array of memory cells 104. Like numbered elements in FIG. 2B correspond to the description as provided with respect to FIG. 2A. FIG. 2B provides additional detail of one example of a three-dimensional NAND memory array structure. For clarity, the GG gates and their control lines are not depicted in FIG. 2B.

The three-dimensional NAND memory array 200B might incorporate vertical structures which might include conductively-doped semiconductor pillars, which might be solid or hollow, around which memory cells of NAND strings 206 might be formed. A portion of a pillar might act as a body or channel (e.g., channel region) of the memory cells of NAND strings 206, e.g., a region through which current might flow when a memory cell, e.g., a field-effect transistor, is activated. Each of the NAND strings 206 might be selectively connected to a data line 204₀-204_{M} through a select gate 212 and to a common source 216 through a select gate 210. Multiple NAND strings 206 might be selectively connected to the same data line 204. Subsets of NAND strings 206 can be connected to their respective data lines 204 by biasing the select lines 215₀-215_{K} to selectively activate particular select gates 212 each between a NAND string 206 and a data line 204. The select gates 210 can be activated by biasing the select line 214. Each access line 202 might be connected to multiple rows of memory cells of the memory array 200B. Rows of memory cells that are commonly connected to each other by a particular access line 202 might collectively be referred to as tiers.

The three-dimensional NAND memory array 200B might be formed over peripheral circuitry 226. The peripheral circuitry 226 might represent a variety of circuitry for accessing the memory array 200B. The peripheral circuitry 226 might include complementary circuit elements. For example, the peripheral circuitry 226 might include both n-channel region and p-channel region transistors formed on a same semiconductor substrate, a process commonly referred to as CMOS, or complementary metal-oxide-semiconductors. Although CMOS often no longer utilizes a strict metal-oxide-semiconductor construction due to advancements in integrated circuit fabrication and design, the CMOS designation generally remains as a matter of convenience.

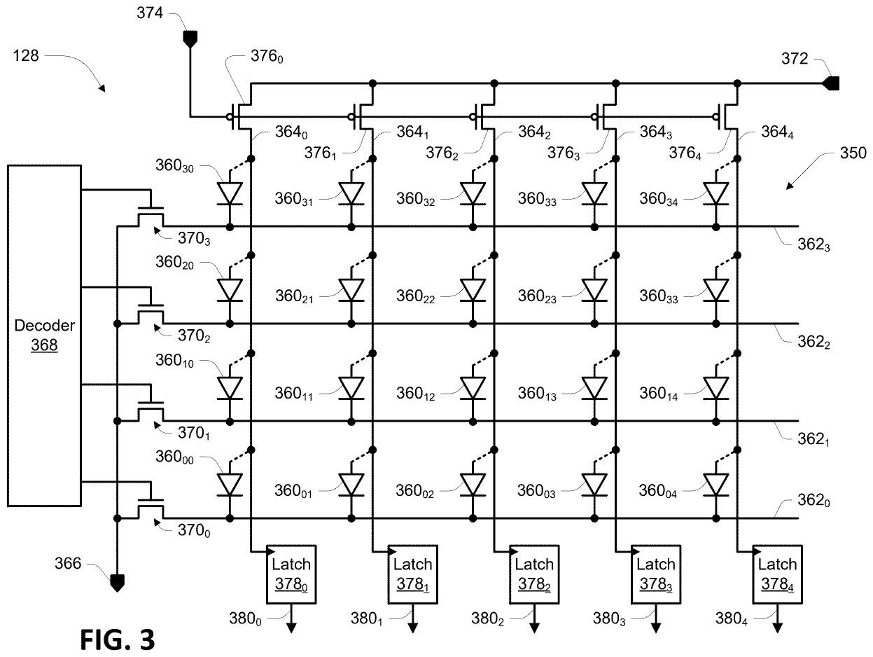

FIG. 3 is a block schematic of a read-only memory 128 in accordance with an embodiment. The read-only memory 128 might include an array of read-only memory cells 350 in the form of diodes 360, e.g., diodes 360₀₀-360₃₄. Each diode 360 might be formed at an intersection of an access line (e.g., word line) 362 and a data line (e.g., bit line) 364. In the example of FIG. 3, the array of read-only memory cells 350 is depicted to include four rows of read-only memory cells, with each row of read-only memory cells having its diodes 360 connected to a respective access line 362. As depicted, the connection of a diode 360 to an access line 362 is the connection of the cathode of the diode 360 to the access line 362.

The array of read-only memory cells 350 in the example of FIG. 3 is further depicted to include five columns of read-only memory cells, with each column of read-only memory cells having each of its diodes 360 optionally connected to a respective data line 364. The optional connection of the diodes 360 to the data lines 364 is indicated by dashed line in FIG. 3. As depicted, the optional connection of a diode 360 to a data line 364 is the optional connection of the anode of the diode 360 to the data line 364.

As will be described in more detail later, a diode 360 that is connected to its respective data line 364 might be configured to store a first data value (e.g., a “1” or logic high) and a diode 360 that is not connected to (e.g., is isolated from) its respective data line 364 might be configured to store a second data value different than the first data value (e.g., a “0” or logic low). Arrays of read-only memory cells 350 might include fewer or more rows of read-only memory cells, and/or might include fewer or more columns of read-only memory cells. For example, typical arrays of read-only memory cells might contain a number of read-only memory cells from 1K to 100K arranged in tens to thousands of rows and tens to hundreds of columns. In addition, a memory 100 might contain more than one read-only memory 128 in communication with its control logic 116.

To access (e.g., to perform a sensing operating on) the array of read-only memory cells 350, a precharge voltage level, e.g., a logic high voltage level such as a supply voltage Vcc, might be applied to the voltage node 372. A control signal might be applied to the control signal node 374, e.g., by the control logic 116, configured to activate the switches 376 (e.g., switches 376₀-376₄) and connect the voltage node 372 to the data lines 364 (e.g., data lines 364₀-364₄). For example, with each switch 376 configured as a p-type field-effect transistor (pFET), a logic low voltage level, e.g., a reference potential such as the supply voltage Vss, 0V, or ground, applied to their control gates might be configured to activate the switches 376. With the precharge voltage level applied to the data lines 364, the latches 378 (e.g., latches 378₀-378₄) might each be set to a logic high value. The control signal applied to the control signal node 374 might then be toggled to a different voltage level configured to deactivate the switches 376 and to isolate the data lines 364 from the voltage node 372. A logic high voltage level might then be maintained on the data lines 364 by their corresponding latches 378. For example, with each switch 376 configured as a p-type field-effect transistor (pFET), a logic high voltage level, e.g., the supply voltage Vcc applied to their control gates might be configured to deactivate the switches 376.

With the latches 378 set, a row of read-only memory cells might then be selected for access, e.g., sensing. For example, if the row of read-only memory cells connected to the access line 362₁ are selected for access, a logic low voltage level, e.g., a reference potential such as the supply voltage Vss, 0V, or ground, might be applied to the voltage node 366. In general, the voltage level applied to the selected access line 362₁ would be sufficiently different than the voltage level applied to the data lines 364 that current would flow through the connected diodes 360 sufficient to toggle the latches 378 connected to data lines 364 that are connected to their respective diodes 360 connected to the selected access line 362₁.

The decoder 368, e.g., in response to address information from the control logic 116, might apply a set of control signals to the switches 370 (e.g., switches 370₀-370₃) configured to deactivate the switches 370₀, 370₂, and 370₃, and to activate the switch 370₁, in order to connect the selected access line 362₁ to the voltage node 366, and to isolate the unselected access lines 362₀, 362₂, and 362₃ from the voltage node 366. For example, with each switch 370 configured as an n-type field-effect transistor (nFET), a logic high voltage level applied to its control gate might be configured to activate that switch 370, and a logic low voltage level applied to its control gate might be configured to deactivate that switch 370. As a result, the selected access line 362₁ might receive the logic low voltage level and the unselected access lines 362₀, 362₂, and 362₃ might be electrically floating.

As a result of connecting the selected access line 362₁ to the voltage node 366 and isolating the unselected data lines 362₀, 362₂, and 362₃ from the voltage node 366, selected diodes 360 (e.g., diodes 360₁₀, 360₁₁, 360₁₂, 360₁₃, and/or 360₁₄) connected to the selected access line 362₁ and having a connection to their respective data line 364 (e.g., data lines 364₁₀, 364₁₁, 364₁₂, 364₁₃, and 364₁₄, respectively) might become forward biased, and might connect their respective data line 364 to the selected access line 362₁, which might cause the voltage level of those data lines 364 to discharge, e.g., to a cut-off voltage level of the diodes 360, which might be around 0.6V for a P-N diode. Such discharge might toggle the corresponding latches 378 to a logic low value at the connection to their respective data line 364. Diodes 360 (e.g., diodes 360₁₀, 360₁₁, 360₁₂, 360₁₃, and/or 360₁₄) that are isolated from their respective data line 364 (e.g., data lines 364₁₀, 364₁₁, 364₁₂, 364₁₃, and 364₁₄, respectively), might have no current path from their respective data line 364 to the selected access line 362₁, which might result in no change to the state of the corresponding latches 378, e.g., latches 378 connected to data lines 364 having no connection to the selected access line 362₁.

The data values of the diodes 360 connected to the selected access line 362 might then be obtained from the outputs 380 of the latches 378. This data might be transmitted to the control logic 116 for its use. Note that the data value of the output 380 of a latch 378 might be the same as the data value of the input (e.g., its data line 364) of the latch 378, or the data value of the output 380 of the latch 378 might be the inverse of the data value of the input of the latch 378.

While the foregoing example described operation of the array of read-only memory cells 350 having cathodes of its diodes 360 connected to access lines 362, the connections could be reversed with the anodes of its diodes 360 connected to the access lines 362 by making corresponding changes to the voltage levels. For example, the latches 378 could be precharged to a logic low voltage level applied to the data lines 364, and a logic high voltage level could be applied to the selected access line 362, resulting in toggling of the latches 378 corresponding to data lines 364 being connected to the cathodes of the diodes 360 that are connected to the selected access line 362, and maintaining the precharged logic low voltage levels on the latches 378 corresponding to data lines 364 being isolated from the cathodes of the diodes 360 that are connected to the selected access line 362.

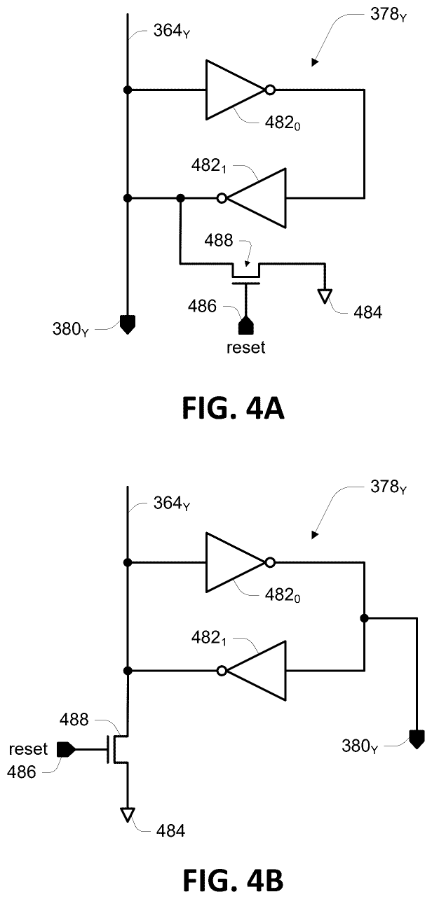

FIGS. 4A-4B are block schematics of latches as a pair of cross-coupled inverters that could be used with embodiments. FIG. 4A depicts a latch 378_{Y}, where Y might be any integer value from 0 to M, where M+1 is a number of columns of read-only memory cells of the array of read-only memory cells 350. The latch 378_{Y} of FIG. 4A is depicted to include a first inverter 482₀ having an input connected to the data line 364_{Y}. The latch 378_{Y} of FIG. 4A is depicted to further include a second inverter 482₁ having an input connected to an output of the first inverter 482₀ and having an output connected to the data line 364_{Y}. The output 380_{Y} of the latch 378_{Y} is depicted to be connected to the input of the first inverter 482₀ and to the output of the second inverter 482₁. Reset circuitry might further be included in the latch 378_{Y} of FIG. 4A. For example, the output of the second inverter 482₁ might be selectively connected to a voltage node 484 through a switch 488. The switch 488 might be configured as an nFET having its control gate connected to a control signal node 486. A reset control signal might be applied to the control signal node 486 configured to activate the switch 488 in order to reset the output of the latch 378_{Y} to a logic low value if desired. Alternatively, the latch 378_{Y} of FIG. 4A might be devoid of reset circuitry as the setting of the latch 378_{Y} during the precharge of a sensing operation can be effective regardless of the state of the latch 378_{Y} prior to the sensing operation.

FIG. 4B depicts a latch 378_{Y}, where Y might be any integer value from 0 to M, where M+1 is a number of columns of read-only memory cells of the array of read-only memory cells 350. The latch 378_{Y} of FIG. 4B is depicted to include a first inverter 482₀ having an input connected to the data line 364_{Y}. The latch 378_{Y} of FIG. 4B is depicted to further include a second inverter 482₁ having an input connected to an output of the first inverter 482₀ and having an output connected to the data line 364_{Y}. The output 380_{Y} of the latch 378_{Y} is depicted to be connected to the output of the first inverter 482₀ and to the input of the second inverter 482₁. Reset circuitry might further be included in the latch 378_{Y} of FIG. 4B. For example, the output of the second inverter 482₁ might be selectively connected to a voltage node 484 through a switch 488. The switch 488 might be configured as an nFET having its control gate connected to a control signal node 486. A reset control signal might be applied to the control signal node 486 configured to activate the switch 488 in order to reset the output of the latch 378_{Y} to a logic high value if desired. Alternatively, the latch 378_{Y} of FIG. 4B might be devoid of reset circuitry as the setting of the latch 378_{Y} during the precharge of a sensing operation can be effective regardless of the state of the latch 378_{Y} prior to the sensing operation.

An array of read-only memory cells of various embodiments might be configured to store a defined (e.g., predetermined) pattern of data at a time of fabrication. Consider the following example of a data pattern as provided in Table 1.

TABLE 1
Example Data Pattern

| | |
|---|---|
| Access | Data Line |

| Line | 364ᵤ | 364ᵥ | 364_{w} | 364_{\x} | 364_{y} | 364_{z} |
|---|---|---|---|---|---|---|
| 362_{f} | 0 | 1 | 1 | 1 | 1 | 0 |
| 362ₑ | 0 | 0 | 1 | 1 | 1 | 0 |
| 362_{d} | 1 | 1 | 1 | 0 | 1 | 0 |
| 362_{c} | 0 | 1 | 0 | 1 | 0 | 1 |
| 362_{b} | 0 | 1 | 0 | 1 | 1 | 0 |
| 362ₐ | 1 | 1 | 0 | 0 | 0 | 1 |

Table 1 provides an example data pattern that might be stored to an array of read-only memory cells (or a portion of an array of read-only memory cells) in accordance with an embodiment, with each data value of the data pattern stored to a read-only memory cell occurring at an intersection of a respective access line 362 (e.g., one of access lines 362ₐ-362_{f}) and a respective data line 364 (e.g., one of data lines 364ᵤ-364_{z}). In this example, the variable “a” might be any integer value from 0 to a number of rows of the array of read-only memory cells minus 6, with b=a+1, c=b+1, d=c+1, e=d+1, and f=e+1, and the variable “u” might be any integer value from 0 to a number of columns of the array of read-only memory cells minus 6, with v=u+1, w=v+1, x=w+1, y=x+1, and z=y+1. As one example, diodes 360 isolated from their respective data line 364 might be configured to store a first data value, e.g., a logic high value or 1, and diodes 360 having a connection to their respective data line 364 might be configured to store a second data value, e.g., a logic low value or 0. As noted with reference to FIGS. 4A-4B, this convention could be reversed if desired.

In addition to data for use by the control logic 116 during operation, data stored to an array of read-only memory cells in accordance with embodiments could further include error correction code (ECC) data to be used in manners well understood in the art of semiconductor memory to correct errors in data read from the array of read-only memory cells. For example, digit errors might occur if a connection is intended between a data line 364 and a diode 360 but the connection is ineffective, if isolation between a data line 364 and a diode 360 is intended but they are shorted to one another, or if a latch 378 is defective. Use of ECC data could facilitate the retrieval of valid data from a defective array of read-only memory cells as long the number of erroneous digits is within the correctable number of the error correction scheme used.

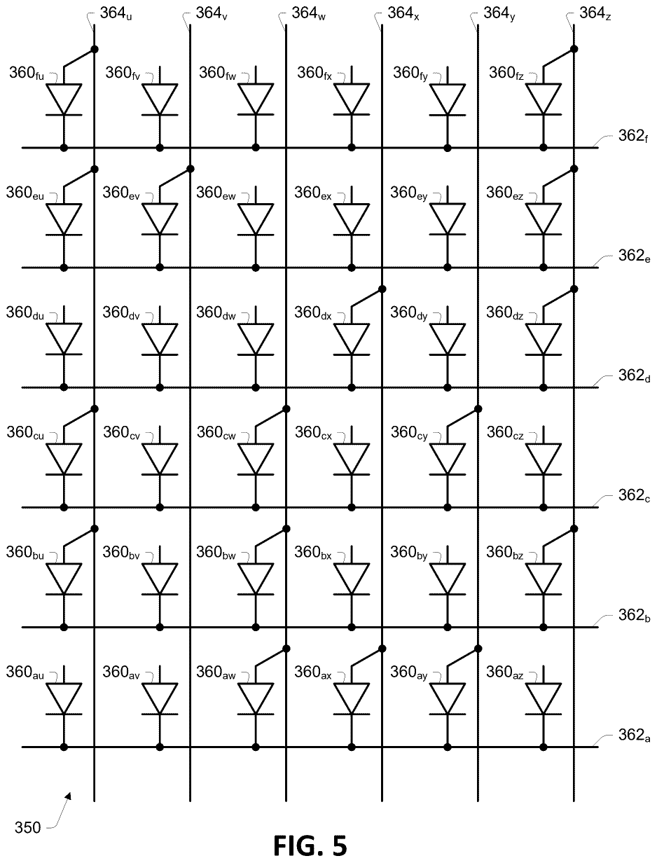

FIG. 5 is a block schematic of a portion of an array of read-only memory cells 350 in accordance with an embodiment storing data of Table 1. In the schematic of FIG. 5, the data of the first data row of Table 1, e.g., 011110, might be stored to the diodes 360_{fu}, 360_{fv}, 360_{fw}, 360_{fx}, 360_{fy}, and 360_{fz} by providing a connection between the diode 360_{fu} and its corresponding data line 364ᵤ and providing a connection between the diode 360_{fz} and its corresponding data line 3642, while maintaining isolation between the data lines 364ᵥ, 364_{w}, 364ₓ, and 364_{y} and their corresponding diodes 360_{fv}, 360_{fw}, 360_{fx}, and 360_{fy}, respectively.

The data of the second data row of Table 1, e.g., 001110, might be stored to the diodes 360ₑᵤ, 360ₑᵥ, 360_{ew}, 360ₑₓ, 360_{ey}, and 360_{ez} by providing a connection between the diode 360ₑᵤ and its corresponding data line 364ᵤ, providing a connection between the diode 360ₑᵥ and its corresponding data line 364ᵥ, and providing a connection between the diode 360_{ez} and its corresponding data line 364_{z}, while maintaining isolation between the data lines 364_{w}, 364ₓ, and 364_{Y} and their corresponding diodes 360_{ew}, 360ₑₓ, and 360_{ey}, respectively.

The data of the third data row of Table 1, e.g., 111010, might be stored to the diodes 360_{du}, 360_{dv}, 360_{dw}, 360_{dx}, 360_{dy}, and 360_{dz} by providing a connection between the diode 360_{dx} and its corresponding data line 364ₓ and providing a connection between the diode 360_{dz} and its corresponding data line 364_{z}, while maintaining isolation between the data lines 364ᵤ, 364ᵥ, 364_{w}, and 364_{y} and their corresponding diodes 360_{du}, 360_{dv}, 360_{dw}, and 360_{dy}, respectively.

The data of the fourth data row of Table 1, e.g., 010101, might be stored to the diodes 360_{cu}, 360_{cv}, 360_{cw}, 360_{cx}, 360_{cy}, and 360_{cz} by providing a connection between the diode 360_{cu} and its corresponding data line 364ᵤ, providing a connection between the diode 360_{cw} and its corresponding data line 364_{w}, and providing a connection between the diode 360_{cy} and its corresponding data line 364_{Y}, while maintaining isolation between the data lines 364ᵥ, 364ₓ, and 364_{z} and their corresponding diodes 360_{cv}, 360_{cx}, and 360_{cz}, respectively.

The data of the fifth data row of Table 1, e.g., 010110, might be stored to the diodes 360_{bu}, 360_{bv}, 360_{bw}, 360_{bx}, 360_{by}, and 360_{bz} by providing a connection between the diode 360_{bu} and its corresponding data line 364ᵤ, providing a connection between the diode 360_{bw} and its corresponding data line 364_{w}, and providing a connection between the diode 360_{bz} and its corresponding data line 364_{z}, while maintaining isolation between the data lines 364ᵥ, 364ₓ, and 364_{y} and their corresponding diodes 360_{bv}, 360_{bx}, and 360_{by}, respectively.

The data of the sixth data row of Table 1, e.g., 110001, might be stored to the diodes 360ₐᵤ, 360ₐᵥ, 360_{aw}, 360ₐₓ, 360_{ay}, and 360_{az} by providing a connection between the diode 360_{aw} and its corresponding data line 364_{w}, providing a connection between the diode 360ₐₓ and its corresponding data line 364ₓ, and providing a connection between the diode 360_{ay} and its corresponding data line 364_{Y}, while maintaining isolation between the data lines 364ᵤ, 364ᵥ, and 364, and their corresponding diodes 360ₐᵤ, 360ₐᵥ, and 360_{az}, respectively.

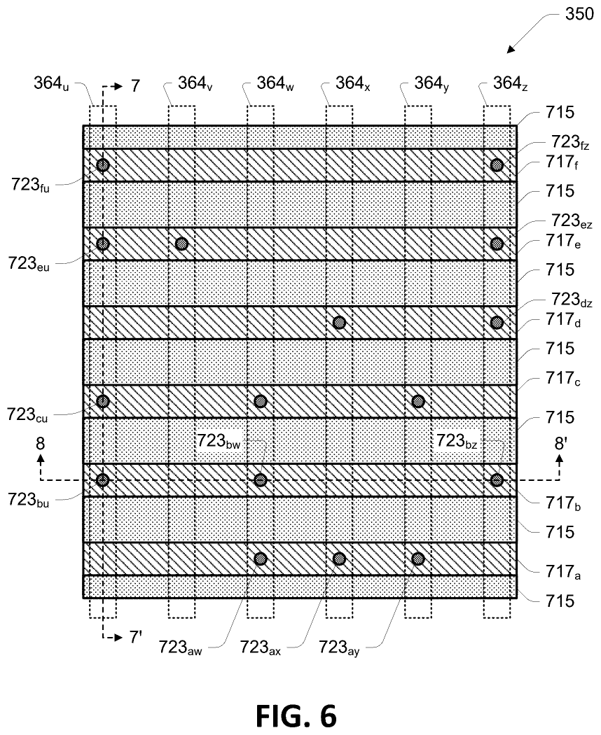

FIG. 6 is a plan view of a portion of an array of read-only memory cells 350 in accordance with an embodiment storing data of Table 1 for use in describing its fabrication. The plan view is taken from a point of view below the data lines 364 and above the anodes of the diodes 360. The plan view of FIG. 6 might depict a portion of an array of read-only memory cells 350 corresponding to the schematic of FIG. 5. Depicted in FIG. 6 are data lines 364 (e.g., data lines 364ᵤ-364_{z}), isolation regions 715 between rows of diodes 360 (not depicted in FIG. 6), p-type conductive regions 717 (e.g., p-type conductive regions 717ₐ-717_{f}), and contacts 723 (e.g., contacts 723_{aw}-723_{fz}) for connection between the anodes of the diodes 360 (e.g., the p-type conductive regions 717) and the data lines 364. The p-type conductive regions 717ₐ-717_{f} might correspond to the access lines 362ₐ-362_{f} (not depicted in FIG. 6), respectively.

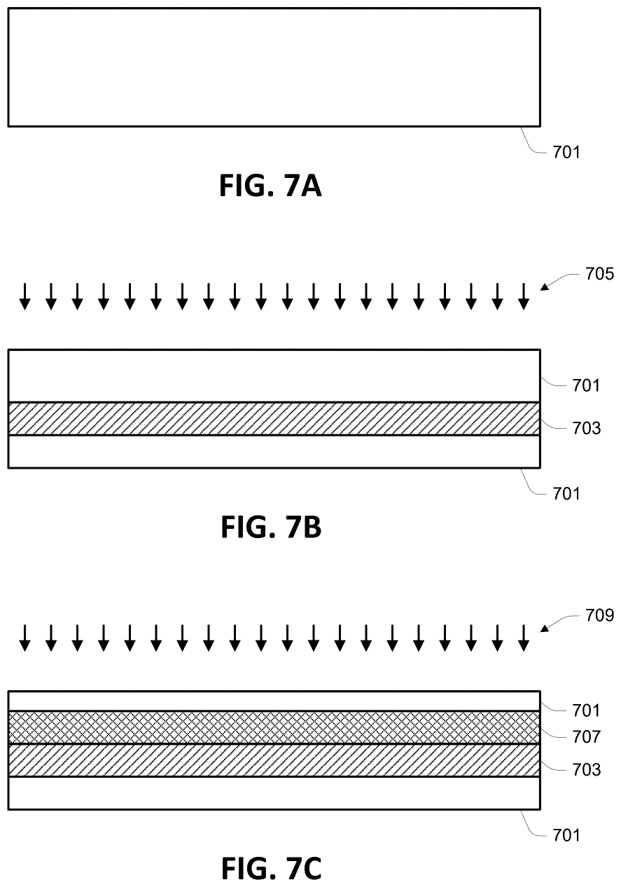

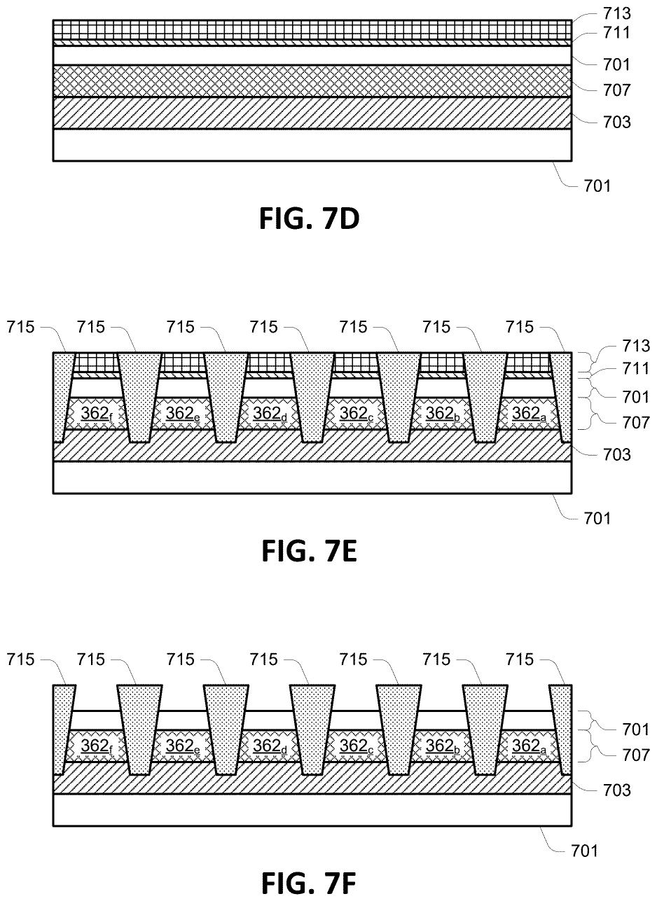

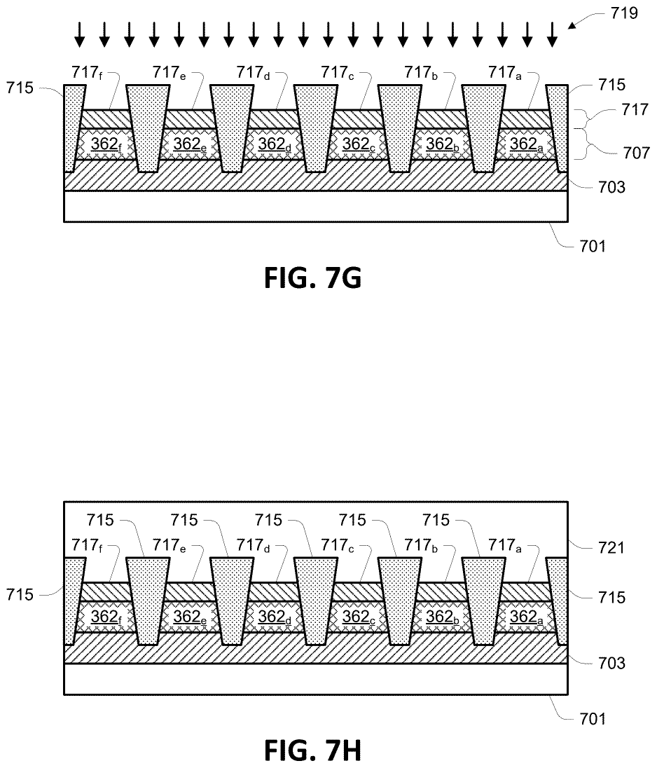

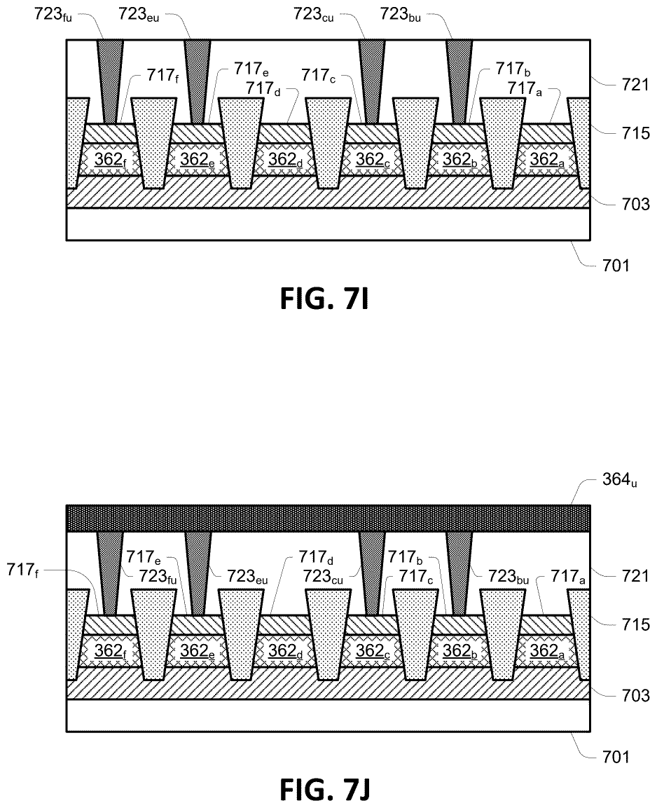

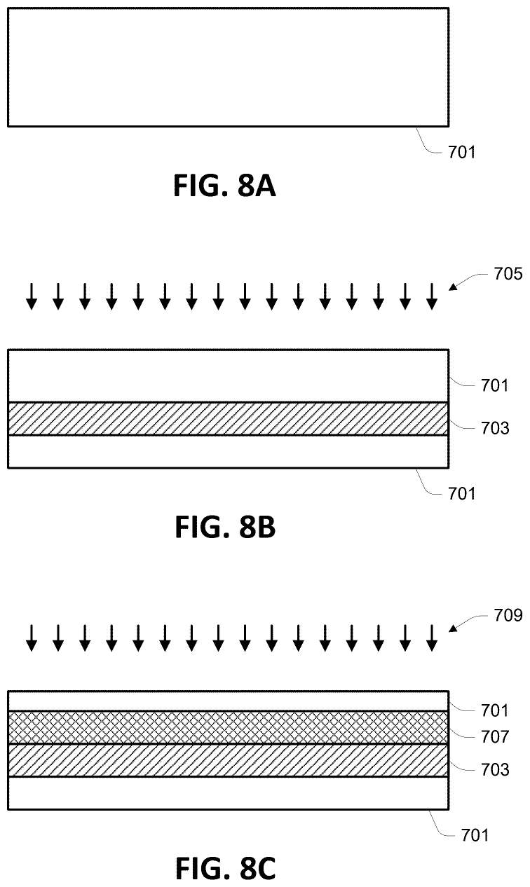

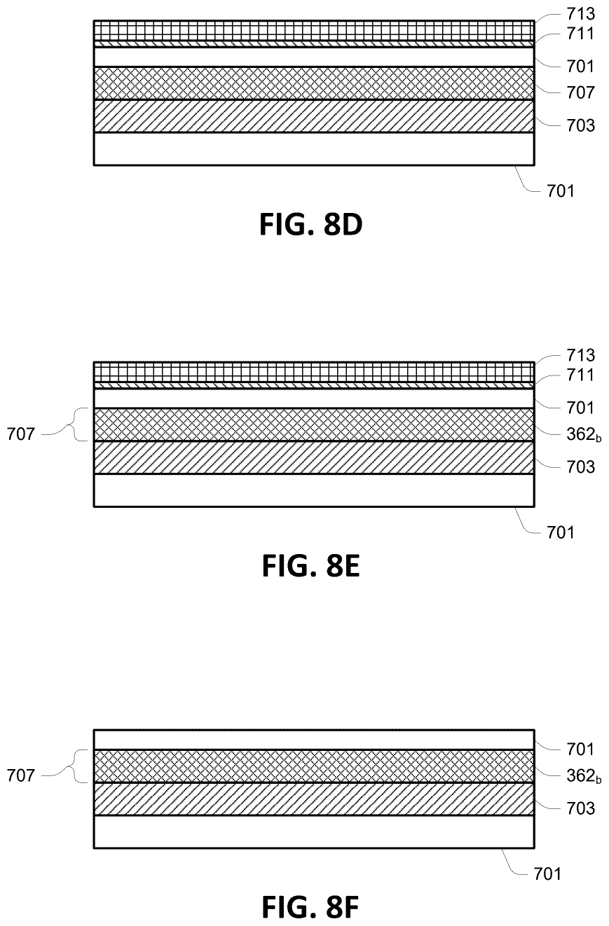

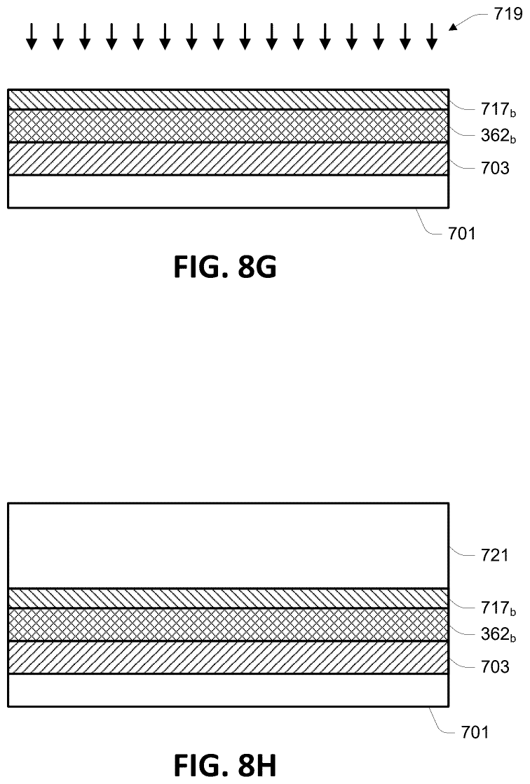

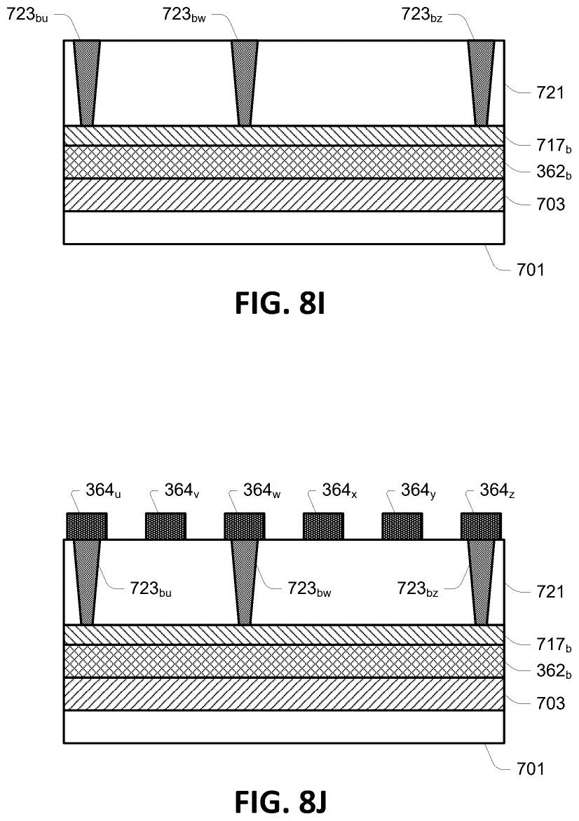

FIGS. 7A-7J are cross-sectional views of the portion of the array of read-only memory cells 350 taken along line 7-7′ of FIG. 6 during various stages of fabrication. FIGS. 8A-8J are cross-sectional views of the portion of the array of read-only memory cells 350 taken along line 8-8′ of FIG. 6, orthogonal to the views of FIGS. 7A-7J, during various stages of fabrication.

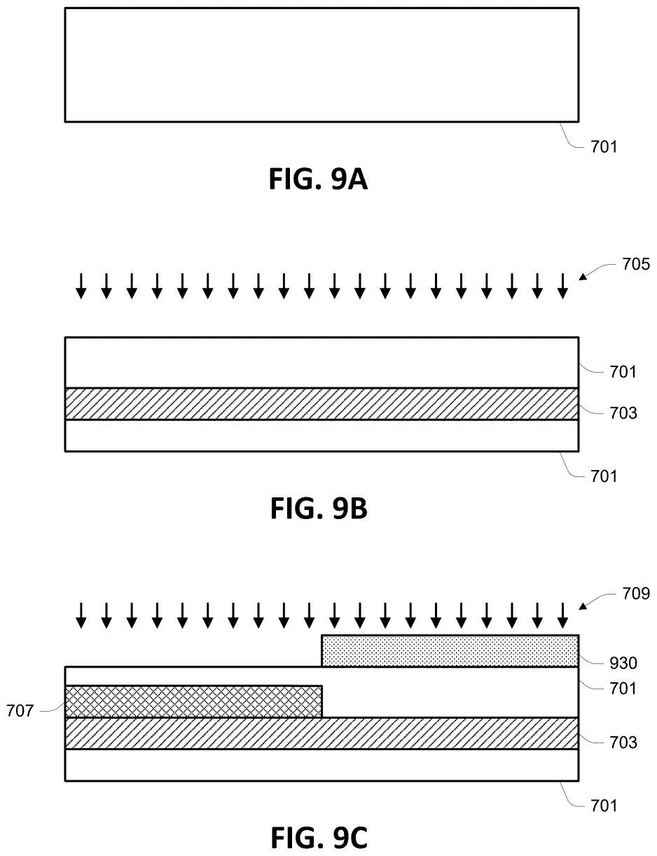

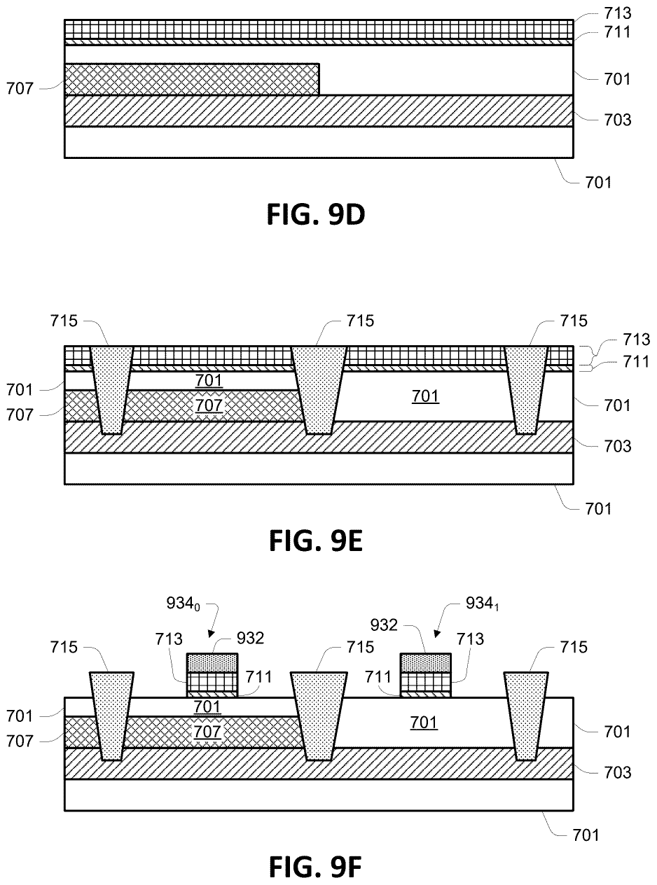

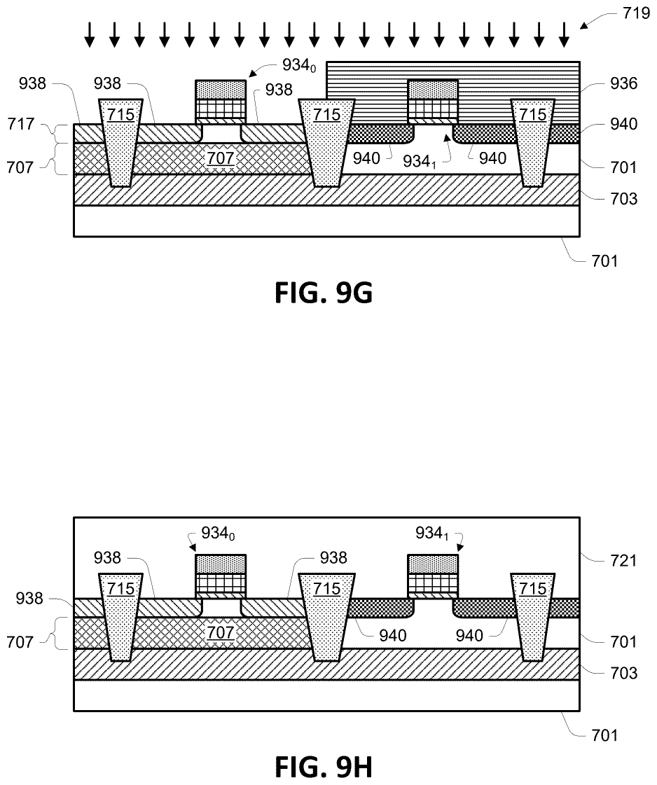

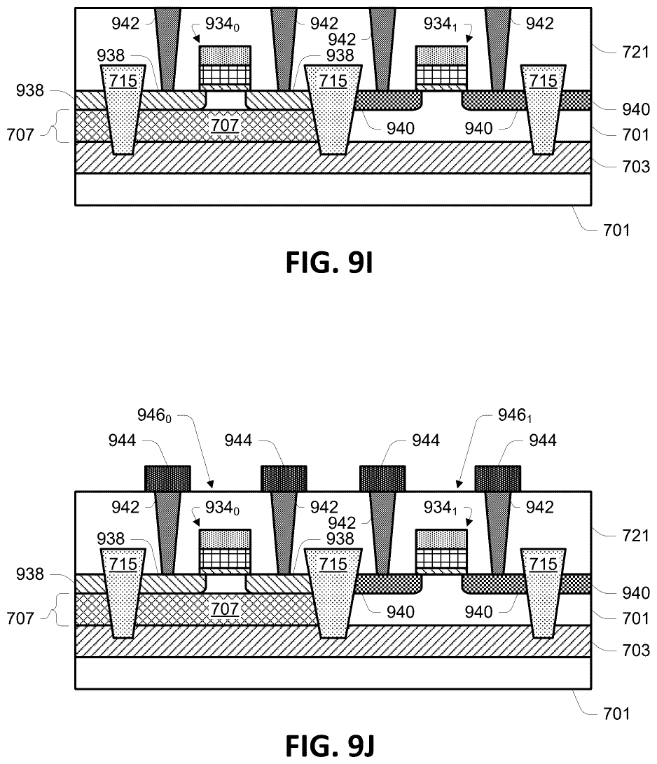

Various embodiments might utilize fabrication techniques used to form complementary (e.g., CMOS) circuitry, e.g., including complementary field-effect transistors. In this manner, the array of read-only memory cells could be formed without performing additional processing steps. Additional processing steps generally increase the time to fabricate a die, and generally increase the risk of making a defective die. As such, fabricating the array of read-only memory cells concurrently with fabricating complementary circuitry of a memory device can facilitate improved processing times and higher yields. For some embodiments, the array of read-only memory cells 350 and the complementary circuitry might be formed as components of a same read-only memory 128. FIGS. 9A-9J are cross-sectional views of CMOS circuitry during various stages of fabrication concurrent with fabrication of the array of read-only memory cells in accordance with embodiments, showing the parallelism of the fabrication techniques.

FIGS. 7A, 8A, and 9A depict a semiconductor 701, that might be formed over some underlying structure (not depicted in FIG. 7A, 8A, or 9A) such as another semiconductor or a dielectric, for example. For one embodiment, the semiconductor 701 might be a silicon-containing semiconductor material, such as monocrystalline silicon. For other embodiments, the semiconductor 701 might be an amorphous or polycrystalline silicon material, or might be some other semiconductor material such as a germanium or silicon-germanium semiconductor. The semiconductor 701 might or might not have an inherent conductivity type, such as a p-type or n-type conductivity.

In FIGS. 7B, 8B and 9B, a first conductive region 703 might be formed in the semiconductor 701. The first conductive region 703 might have a first conductivity type. The first conductivity type might be a p-type conductivity or an n-type conductivity. For at least one embodiment, the first conductivity type might be a p-type conductivity. The first conductive region 703 might be formed by implanting one or more dopant species into the semiconductor 701. As is well understood in the art, such implantation (e.g., beam-line implantation) might commonly involve acceleration of ions directed at a surface of the semiconductor 701 such as conceptually depicted by arrows 705. An energy of the implant might be selected to produce the first conductive region 703 below an uppermost surface of the semiconductor 701. To produce a p-type conductivity, the dopant species might include ions of boron (B), indium (In) or another p-type impurity. To produce an n-type conductivity, the dopant species might include ions of arsenic (As), antimony (Sb), phosphorus (P) or another n-type impurity. Other methods of forming conductive regions in a semiconductor are known and embodiments herein are not limited to any method of forming the conductive regions. The first conductive region 703 might use an energy and dopant dose configured to form a p-well approximately 0.25 μm from the uppermost surface of the semiconductor 701. The dopant concentration, e.g., boron, might be on the order of 1E16-1E18/cm\hat{ }3.

In FIGS. 7C, 8C, and 9C, a second conductive region 707 might be formed in the semiconductor 701 overlying the first conductive region 703. The second conductive region 707 might have a second conductivity type different than (e.g., opposite of) the first conductivity type. For at least one embodiment, the second conductivity type might be an n-type conductivity. The second conductive region 707 might be formed by implanting one or more dopant species into the semiconductor 701. As is well understood in the art, such implantation might commonly involve acceleration of ions directed at a surface of the semiconductor 701 such as conceptually depicted by arrows 709. In FIG. 9C, a mask 930 might be formed over a portion of the semiconductor 701, such that the second conductive region 707 is formed in only a portion of the active area for complementary circuitry. Subsequent to forming the second conductive region 707, the mask 930 might be removed.

The second conductive region 707 might be formed to be in contact with the first conductive region 703, or it might be formed to be spaced apart from the first conductive region 703. The second conductive region 707 might be formed by implanting one or more dopant species into the semiconductor 701. For example, the second conductive region 707 might be formed using a beam-line implantation process with a phosphorus impurity using a tilt of 7°, a power level of approximately 120 keV, and a dopant dose of approximately 8E14/cm\hat{ }2. With such an implantation process, the second conductive region 707 might have a peak doping on the order of 3E19/cm\hat{ }3 around a depth of 0.12 μm, and might generally range from 1E18-1E20/cm\hat{ }3.

In FIGS. 7D, 8D, and 9D, a dielectric 711 might be formed overlying the uppermost surface of the semiconductor 701 and a conductor 713 might be formed overlying the uppermost surface of the dielectric 711. The dielectric 711 might generally be formed of one or more dielectric materials, while the conductor 713 might generally be formed of one or more conductive materials. The dielectric 711 might correspond to a gate dielectric of one or more future transistors, while the conductor 466 might correspond to a control gate of those one or more future transistors. For example, the dielectric 711 might comprise, consist of, or consist essentially of an oxide, e.g., silicon dioxide, and/or might comprise, consist of, or consist essentially of a high-K dielectric material, such as aluminum oxides (AlOₓ), hafnium oxides (HfOₓ), hafnium aluminum oxides (HfAlOₓ), hafnium silicon oxides (HfSiOₓ), lanthanum oxides (LaOₓ), tantalum oxides (TaOₓ), zirconium oxides (ZrOₓ), zirconium aluminum oxides (ZrAlOₓ), or yttrium oxide (Y₂O₃), as well as any other dielectric material. The conductor 713 might comprise, consist of, or consist essentially of conductively doped polysilicon and/or might comprise, consist of, or consist essentially of metal, such as a refractory metal, or a metal-containing material, such as a refractory metal silicide or a metal nitride, e.g., a refractory metal nitride, as well as any other conductive material.

In FIGS. 7E, 8E, and 9E, isolation regions 715 might be formed to extend from an uppermost surface of the conductor 713 to a level below the second conductive region 707 and into the first conductive region 703, thereby defining access lines 362ₐ-362_{f} and isolating them from one another. For a second conductive region 707 having an n-type conductivity, the access lines 362 might both be connected to, and form, the cathodes of the future diodes. The access lines 362 might each extend in a first direction, e.g., into the face plane of FIG. 7E and parallel to the face plane of FIG. 8E.

The isolation regions 715 might be shallow-trench isolation (STI) structures. Formation of the isolation regions 715 might include forming trenches extending into the face plane of FIG. 7E (see, e.g., FIG. 6) and into the face plane of FIG. 9E, and filling the trenches with one or more dielectric materials. Filling the trenches with dielectric material might include a high-density plasma (HDP) deposition and/or spin-on dielectric (SOD) process, for example. Filling the trenches with dielectric material might alternatively include chemical vapor deposition (CVD), low-pressure CVD (LPCVD), physical vapor deposition (PVD) or atomic layer deposition (ALD). An etch process or chemical-mechanical planarization (CMP) might be used to remove excess dielectric material from above the uppermost surface of the conductor 713.

In FIGS. 7F, 8F, and 9F, portions of the conductor 713 and dielectric 711 might be removed. This might include removal of substantially all (e.g., all) of the conductor 713 and dielectric 711 overlying portions of the array of read-only memory cells. As depicted in FIG. 9F, a mask 932 might be formed overlying portions of the conductor 713 and dielectric 711 that are to remain. The individual instances of a mask 932, conductor 713 and dielectric 711 might collectively form a gate stack 934, such as the gate stack 934₀ on the left of FIG. 9F and the gate stack 934₁ on the right of FIG. 9F. The gate stacks 934₀ and 934₁ might correspond to gate stacks of future complementary field-effect transistors. Although not depicted in FIG. 9F, dielectric spacers are commonly formed on sidewalls of the gate stacks 934 after their definition and before forming corresponding source/drain regions.

In FIGS. 7G and 8G, third conductive regions 717 might be formed in the semiconductor 701 overlying the second conductive region 707 between isolation regions 715, while in FIG. 9G, third conductive regions 717 might be formed in exposed portions of the semiconductor 701 overlying the third conductive region 707, forming source/drain regions 938, which might extend partially under their corresponding gate stack 934₀. FIG. 9G further depicts source/drain regions 940 formed in the semiconductor 701 underlying the mask 936. These source/drain regions might be formed to have the second conductivity type before forming the source/drain regions 938 and after defining the gate stack 934 in FIG. 9F (e.g., as depicted in FIG. 9G), or after forming the source/drain regions 938 and prior to the processing of FIG. 9H. During the formation of source/drain regions 940 of the second conductivity type, areas in which a third conductive region 717 is to be formed might be covered by another mask (not depicted in the figures) while the areas for formation of the source/drain regions 940 are exposed. After formation of the source/drain regions 938, the mask 936 might be removed.

Each third conductive region 717 might have the first conductivity type. Each third conductive region 717 might be formed by implanting dopant species into the semiconductor 701. As is well understood in the art, such implantation might commonly involve acceleration of ions directed at a surface of the semiconductor 701 such as conceptually depicted by arrows 719.

Each third conductive region 717 of FIG. 7G (e.g., third conductive regions 717ₐ-717_{f}) might be formed to be in contact with a respective access line 362 (e.g., access lines 362ₐ-362_{f}). For the example conductivities used in discussion of the figures, these third conductive regions 717 might form anodes of the resulting diodes, e.g., the p-n junction formed by each p-type third conductive region 717 and its corresponding n-type access line 362.

The third conductive regions 717 might use an energy and dopant dose configured to form the third conductive regions 717 extending from the uppermost surface of the semiconductor 701 to a level in contact with their corresponding access lines 362 or second conductive region 707. The dopant concentration, e.g., boron, might be on the order of 1E18-1E20/cm\hat{ }3. For some embodiments, the third conductive regions 717 might extend from an uppermost surface of the semiconductor 701 to a depth of around 0.05 μm, the access lines 362 (e.g., the second conductive region 707) might extend from a depth of around 0.05 μm to around 0.25 μm, and the first conductive region 703 might extend from a depth of around 0.25 μm to around 0.5 μm or lower.

In FIGS. 7H, 8H, and 9H, a dielectric 721 might be formed overlying the isolation regions 715, the third conductive regions 717, and the gate stacks 934. The dielectric 721 might contain one or more dielectric materials. The dielectric 721 might be formed using chemical vapor deposition (CVD), low-pressure CVD (LPCVD), physical vapor deposition (PVD) or atomic layer deposition (ALD). The dielectric 721 might comprise, consist of, or consist essentially of an oxide, e.g., silicon dioxide (SiO₂). The dielectric 721 might alternatively comprise, consist of, or consist essentially of a spin-on dielectric material, e.g., hydrogen silsesquioxane (HSQ), hexamethyldisiloxane, octamethyltrisiloxane, etc., or a high-density-plasma (HDP) oxide. A chemical-mechanical planarization (CMP) process might be used to level the uppermost surface of the dielectric 721.

In FIGS. 7I and 8I, contacts 723 might be formed to extend to be in contact with (and connected to) their respective third conductive regions 717 for those diodes 360 configured to have a connection to their respective data line 364. In FIG. 71, contacts 723_{fu}, 723ₑᵤ, 723_{cu}, and 723_{bu} are depicted to be in contact with their respective third conductive regions 717_{f}, 717ₑ, 717_{c}, and 717_{b}, respectively. In FIG. 8I, contacts 723_{bu}, 723_{bw}, and 723_{bz} are depicted to be in contact with their respective third conductive region 717_{b}. In FIG. 9I, contacts 942 might be formed to extend to be in contact with (and connected to) their source/drain regions 938 of the first conductivity type and respective source/drain regions 940 of the second conductivity type. Although not depicted, contacts could likewise be formed to extend to be in contact with (and connected to) the conductors 713 of the gate stacks 934₀ and 934₁.

Formation of the contacts 723 might include forming vias in the dielectric 721 to expose portions of the third conductive regions 717 intended to have contact with one or more corresponding data lines 364, such as by reactive-ion etching (REI), and filling or lining those vias with conductive material to form the contacts 723. Formation of the contacts 942 might include forming vias in the dielectric 721 to expose portions of the source/drain regions 938 and source/drain regions 940, such as by reactive-ion etching (REI), and filling or lining those vias with conductive material to form the contacts 942.

The contacts 723 and 942 might each contain one or more conductive materials. For some embodiments, the contacts 723 and 942 might each contain the same one or more conductive materials, e.g., formed concurrently. Each contact 723 or 942 might comprise, consist of, or consist essentially of conductively doped polysilicon and/or might comprise, consist of, or consist essentially of metal, such as a refractory metal, or a metal-containing material, such as a refractory metal silicide or a metal nitride, e.g., a refractory metal nitride, as well as any other conductive material. The metals of chromium (Cr), cobalt (Co), hafnium (Hf), molybdenum (Mo), niobium (Nb), tantalum (Ta), titanium (Ti), tungsten (W), vanadium (V) and zirconium (Zr) are generally recognized as refractory metals. As one example, each contact 723 or 942 might include titanium nitride (TiN) formed overlying each third conductive region 717 or source/drain region 938/940, respectively, and tungsten formed overlying the titanium nitride.

In FIGS. 7J and 8J, data lines 364 (e.g., data lines 364ᵤ-364_{z}) might be formed to be in contact with (and connected to) any corresponding contacts 723. In FIG. 9J, conductors 944 might be formed to be in contact with (and connected to) their corresponding contacts 942. Formation of the data lines 364 and conductors 944 might include forming a layer of conductive material, and patterning that layer to define the individual data lines 364 and conductors 944. The data lines 364 might each extend in a second direction different than the first direction, e.g., parallel to the face plane of FIG. 7J and into the face plane of FIG. 8J. Although the data lines 364 are depicted to be orthogonal to the access lines 362, e.g., the second direction being orthogonal to the first direction, the second direction could be some other angle relative to the first direction.

Each data line 364 and conductor 944 might contain one or more conductive materials. For some embodiments, each data line 364 and conductor 944 might contain the same one or more conductive materials. Each data line 364 or conductor 944 might comprise, consist of, or consist essentially of metal, such as a refractory metal, or a metal-containing material, such as a refractory metal silicide or a metal nitride, e.g., a refractory metal nitride, as well as any other conductive material. As one example, the data lines 364 and conductors 944 might comprise, consist of, or consist essentially of a refractory metal, such as tungsten.

In FIG. 9J, the gate stack 934₀ and the source/drain regions 938 on either side of the gate stack 934₀ might form a first field-effect transistor 946₀, and the gate stack 934₁ and the source/drain regions 940 on either side of the gate stack 934₁ might form a second field-effect transistor 946₁. With the example conductivity types, the first field-effect transistor 946₀ might be a p-type field-effect transistor and the second field-effect transistor 946₁ might be an n-type field-effect transistor. The first field-effect transistor 946₀ and the second field-effect transistor 946₁ might correspond to transistors of the control logic 116 or another block component of FIG. 1. As one example, the first field-effect transistor 946₀ could be a switch 376 of the read-only memory 128 of FIG. 3, and the second field-effect transistor 946₁ could be a switch 370 of the read-only memory 128 of FIG. 3. Alternatively, the field-effect transistors 946 could be transistors of other block components of the memory 100.

As can be seen with reference to FIG. 8J, during an access operation (e.g., sensing operation) such as described with reference to FIG. 3, if the access line 362_{b} were selected for the access operation, and if the voltage level of the selected access line 362_{b} were lower than the precharged voltage level of the data lines 364ᵤ-364_{z}, e.g., a logic low voltage level on the selected access line 362_{b} and a logic high voltage level on the data lines 364, latches 378 connected to the data lines 364ᵤ, 364_{w}, and 364_{q} might be toggled due to the discharge of these data lines 364 to the selected access line 362_{b}, and latches 378 connected to the data lines 364ᵥ, 364ₓ, and 364_{y} might maintain their precharged value due to the isolation of these data lines 364 from the selected access line 362_{b.}

If the conductivity types were to be reversed from the foregoing example, e.g., with the first conductivity type being an n-type conductivity and the second conductivity type being a p-type conductivity, and the data lines 364 were to be precharged to a logic low voltage level and a logic high voltage level were to be applied to the selected access line 362_{b}, a similar result could be attained. For example, latches 378 connected to the data lines 364ᵤ, 364_{w}, and 364_{z} might be toggled due to the charging of these data lines 364 from the selected access line 362_{b}, and latches 378 connected to the data lines 364ᵥ, 364ₓ, and 364_{y} might maintain their precharged value due to the isolation of these data lines 364 from the selected access line 362_{b.}

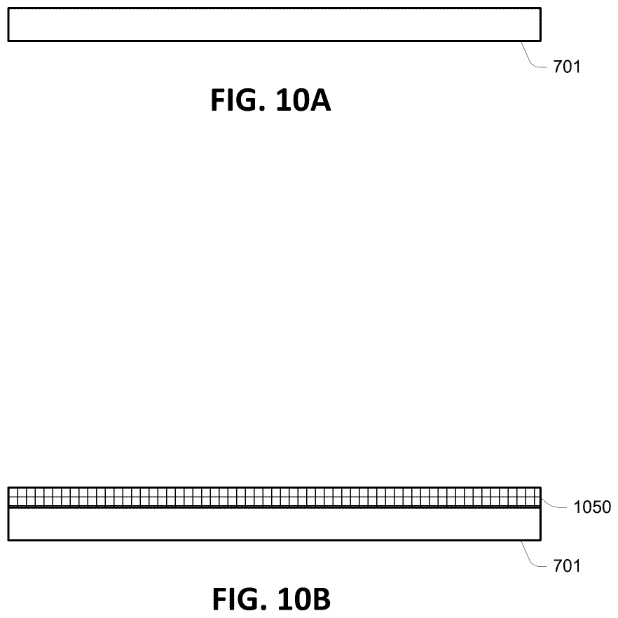

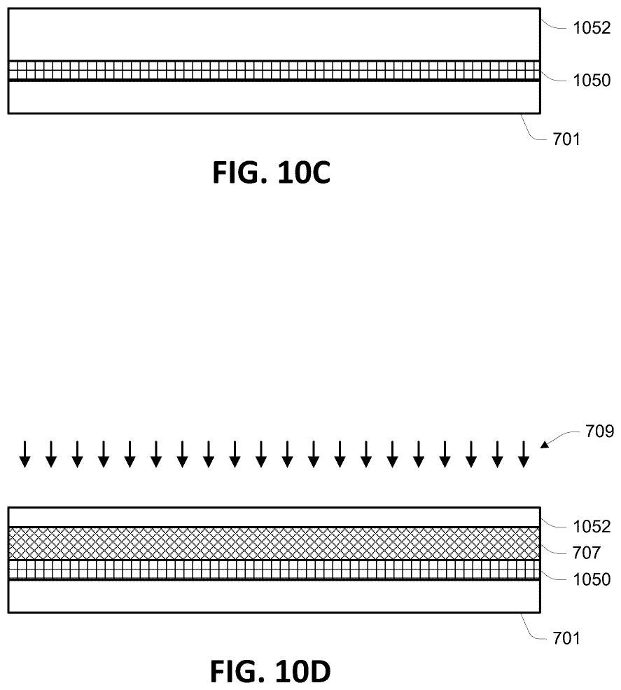

Although advantages might be achieved by forming the array of read-only memory cells concurrently with forming complementary circuitry, the array of read-only memory cells might be formed independently of complementary circuitry, and might use different fabrication techniques and/or materials. As one example, the first conductive region 703 might be eliminated and replaced by a dielectric. FIGS. 10A-10D are cross-sectional views of the portion of the array of read-only memory cells 350 of FIG. 6, corresponding to a same cross-section as the views of FIGS. 7A-7J, during various stages of fabrication in accordance with such an embodiment. Like numbered elements in FIGS. 10A-10D correspond to the description as provided with respect to FIGS. 7A-7C.

FIG. 10A depicts the semiconductor 701. In FIG. 10B, a dielectric 1050 might be formed overlying the semiconductor 701. The dielectric 1050 might generally be formed of one or more dielectric materials. For example, the dielectric 1050 might comprise, consist of, or consist essentially of an oxide, e.g., silicon dioxide, and/or might comprise, consist of, or consist essentially of a high-K dielectric material, such as aluminum oxides (AlOₓ), hafnium oxides (HfOₓ), hafnium aluminum oxides (HfAlOₓ), hafnium silicon oxides (HfSiOₓ), lanthanum oxides (LaOₓ), tantalum oxides (TaOₓ), zirconium oxides (ZrOₓ), zirconium aluminum oxides (ZrAlOₓ), or yttrium oxide (Y₂O₃), as well as any other dielectric material. Forming the dielectric 1050 might include chemical vapor deposition (CVD), low-pressure CVD (LPCVD), physical vapor deposition (PVD) or atomic layer deposition (ALD).

In FIG. 10C, a semiconductor 1052 might be formed overlying the dielectric 1050. The semiconductor 1052 might be a silicon-containing semiconductor material, such as a polycrystalline silicon material (e.g., commonly referred to as polysilicon). Alternatively, the semiconductor 1052 might be an amorphous or monocrystalline silicon material, or might be some other semiconductor material such as a germanium or silicon-germanium semiconductor. The semiconductor 1052 might or might not have an inherent conductivity type, such as a p-type or n-type conductivity. Forming the semiconductor 1052 might include chemical vapor deposition (CVD), low-pressure CVD (LPCVD), physical vapor deposition (PVD) or atomic layer deposition (ALD).

In FIG. 10D, the conductive region 707 might be formed in the semiconductor 1052 overlying the dielectric 1050, such as through the acceleration of ions directed at a surface of the semiconductor 1052 such as conceptually depicted by arrows 709. Further processing might proceed as described with reference to FIGS. 7D-7J and 8D-8J to fabricate the array of read-only memory cells 350.

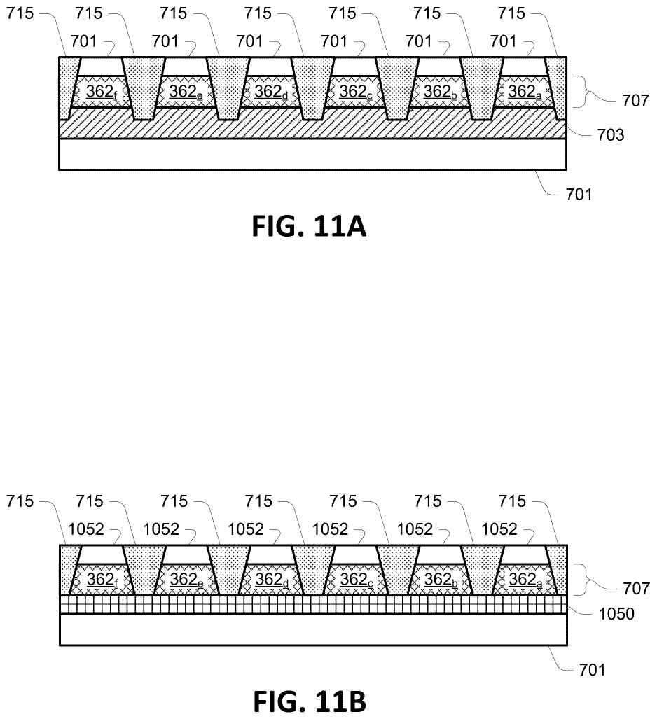

While forming the array of read-only memory cells concurrently with forming complementary circuitry produced isolation regions 715 extending above an uppermost surface of the third conductive regions 717, forming the array of read-only memory cells independently of complementary circuitry might include isolation regions 715 having uppermost surfaces even with the uppermost surfaces of the third conductive regions 717. FIGS. 11A and 11B are cross-sectional views of a portion of the array of read-only memory cells depicting isolation structures in accordance with such embodiments.

FIG. 11A is a cross-sectional view of the portion of the array of read-only memory cells 350 of FIG. 6, corresponding to a same cross-section as the views of FIGS. 7A-7J, depicting alternate isolation structures in accordance with an embodiment. Like numbered elements in FIG. 11A correspond to the description as provided with respect to FIGS. 7A-7E.

In FIG. 11A, after performing the processing as described with reference to FIGS. 7A-7C, isolation regions 715 might be formed to extend from an uppermost surface of the semiconductor 701 to a level below the second conductive region 707 and into the first conductive region 703, thereby defining access lines 362ₐ-362_{f} and isolating them from one another. Further processing might proceed as described with reference to FIGS. 7G-7J and 8G-8J to fabricate the array of read-only memory cells 350.

FIG. 11B is a cross-sectional view of the portion of the array of read-only memory cells 350 of FIG. 6, corresponding to a same cross-section as the views of FIGS. 10A-10D, depicting alternate isolation structures in accordance with another embodiment. Like numbered elements in FIG. 11B correspond to the description as provided with respect to FIGS. 7A-7E and FIG. 10C.

In FIG. 11B, after performing the processing as described with reference to FIGS. 10A-10D, isolation regions 715 might be formed to extend from an uppermost surface of the semiconductor 1052 to a level of the uppermost surface of the dielectric 931 or below, thereby defining access lines 362ₐ-362_{f} and isolating them from one another. Further processing might proceed as described with reference to FIGS. 7G-7J and 8G-8J to fabricate the array of read-only memory cells 350.

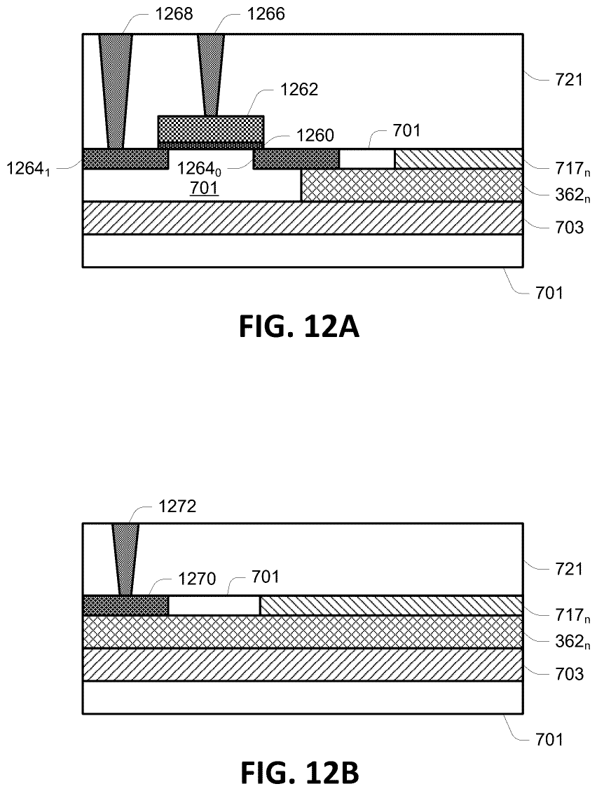

FIGS. 12A-12B are cross-sectional views showing possible connection paths to access lines 362 of an array of read-only memory cells in accordance with embodiments. In FIG. 12A, an access line 362n (e.g., the second conductive region 707) might not extend a full distance (e.g., length or width) of the first conductive region 703, leaving a portion of the semiconductor 701 without a corresponding second conductive region 707 (e.g., an access line 362) overlying the first conductive region 703. The variable “n” might represent any integer value from 0 to a number of rows of read-only memory cells of the array of read-only memory cells minus 1. Similarly, the corresponding third conductive region 717, might not extend a full distance (e.g., length or width) of the access line 362n, leaving a portion of the semiconductor 701 without its corresponding third conductive region 717ₙ overlying a portion of the access line 362n.

A dielectric 1260 (e.g., a gate dielectric) might be formed overlying the semiconductor 701 overlying the first conductive region 703, and a conductor 1262 (e.g., a control gate) might be formed overlying the dielectric 1260. Source/drain regions 12640 and 12641 might then be formed in the semiconductor 701 adjacent both sides of the dielectric 1260 to have a same conductivity type as the access line 362ₙ. The source/drain regions 1264 might be formed concurrently with forming the source/drain regions 940 of FIG. 9G.

One source/drain region 12640 might be formed to be in contact with the access line 362n. A first contact 1266 might be formed to be in contact with the conductor 1262, and a second contact 1268 might be formed to be in contact with the other source/drain region 12641. The transistor formed from the conductor 1262, dielectric 1260 and source/drain regions 12640-12641 might correspond to a switch 370 in communication with the decoder 368 of FIG. 3 through the first contact 1266. The second contact 1268 might be configured to be connected to the voltage node 366.

In FIG. 12B, a third conductive region 717n might not extend a full distance (e.g., length or width) of its corresponding access line 362n, leaving a portion of the semiconductor 701 without a corresponding third conductive region 717ₙ overlying a portion of the access line 362n. The variable “n” might represent any integer value from 0 to a number of rows of read-only memory cells of the array of read-only memory cells minus 1. A fourth conductive region 1270 might then be formed in the semiconductor 701 to be in contact with the access line 362n and to have a same conductivity type as the access line 362n. The fourth conductive region 1270 might be formed concurrently with forming the source/drain regions 940 of FIG. 9G.

A contact 1272 might be formed to be in contact with the fourth conductive region 1270. The contact 1272 might be configured to be connected to a switch 370 in communication with the decoder 368 of FIG. 3. For example, if the switch 370 is an nFET, the contact 1272 might be configured to be connected to one source/drain region of the nFET, and the other source/drain region of the nFET might be configured to be connected to the voltage node 366.

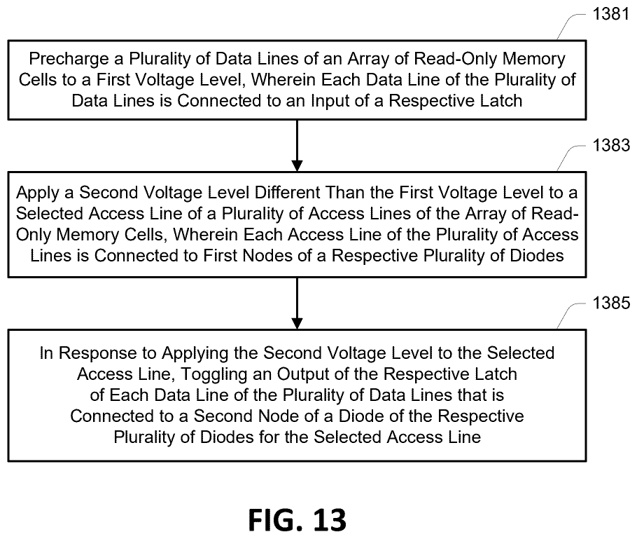

FIG. 13 is a flowchart of a method of operating a read-only memory in accordance with an embodiment, e.g., during a sense operation on an array of read-only memory cells. The method might be in the form of computer-readable instructions, e.g., stored to the instruction registers 127. Such computer-readable instructions might be executed by a controller, e.g., the control logic 116, to cause the memory (e.g., relevant components of the memory) to perform the method.

At 1381, a plurality of data lines of an array of read-only memory cells might be precharged to a first voltage level. For example, the data lines 364 of the array of read-only memory cells 350 of the read-only memory 128 might be precharged to a logic high voltage level. Each data line of the plurality of data lines might be connected to an input of a respective latch. For example, each data line 364 of the array of read-only memory cells 350 of the read-only memory 128 might be connected to an input of a respective latch 378. The precharge might set the respective latches to a first data value. The data lines might then be isolated the first voltage level of the precharge.

At 1383, a second voltage level different than the first voltage level might be applied to a selected access line of a plurality of access lines of the array of read-only memory cells. For example, a logic low voltage level might be applied to a selected access line 362 of the array of read-only memory cells 350 of the read-only memory 128. Each access line of the plurality of access lines might be connected to first nodes of a respective plurality of diodes. The first nodes might be cathodes or anodes of the diodes. For example, each access line 362 of the array of read-only memory cells 350 of the read-only memory 128 might be connected to the cathodes of a respective plurality of diodes 360.

At 1385, in response to applying the second voltage level to the selected access line, an output of the respective latch of each data line of the plurality of data lines that is connected to a second node of a diode of the respective plurality of diodes for the selected access line might be toggled. For example, each data line 364 of the array of read-only memory cells 350 of the read-only memory 128 that is connected to the anode of a diode 360 that is connected to the selected access line 362 might discharge to the selected access line 362 and cause its corresponding latch to toggle to a second data value.

### CONCLUSION

Although specific embodiments have been illustrated and described herein, it will be appreciated by those of ordinary skill in the art that any arrangement that is calculated to achieve the same purpose might be substituted for the specific embodiments shown. Many adaptations of the embodiments will be apparent to those of ordinary skill in the art. Accordingly, this application is intended to cover any adaptations or variations of the embodiments.

What is claimed is:

1. A read-only memory, comprising:
a plurality of access lines extending in a first direction and having a first conductivity type;
a plurality of conductive regions extending in the first direction, wherein each conductive region of the plurality of conductive regions is overlying a respective access line of the plurality of access lines, and wherein each conductive region of the plurality of conductive regions has a second conductivity type different than the first conductivity type;
a dielectric overlying the plurality of conductive regions;
a plurality of data lines extending in a second direction different than the first direction and overlying the dielectric; and
a plurality of contacts, wherein each contact of the plurality of contacts is formed in the dielectric at an intersection of a respective data line of the plurality of data lines and a respective conductive region of the plurality of conductive regions to connect its respective data line to its respective conductive region, and wherein a number of contacts of the plurality of contacts is less than a number of data lines of the plurality of data lines times a number of access lines of the plurality of access lines.

2. The read-only memory of claim 1, wherein the plurality of conductive regions is a plurality of first conductive regions, and wherein the read-only memory further comprises a second conductive region underlying the plurality of access lines, wherein the second conductive region has the second conductivity type.

3. The read-only memory of claim 2, further comprising:
a plurality of isolation regions;
wherein each access line of the plurality of access lines and its respective conductive region of the plurality of first conductive regions are between a respective pair of isolation regions of a plurality of isolation regions; and
wherein each isolation region of the plurality of isolation regions extends below the plurality of access lines and into the second conductive region.

4. The read-only memory of claim 2, wherein the plurality of access lines are in contact with the second conductive region, and wherein each first conductive region of the plurality of first conductive regions is in contact with its respective access line of the plurality of access lines.

5. The read-only memory of claim 2, wherein the plurality of access lines are devoid of contact with the second conductive region, and wherein each first conductive region of the plurality of first conductive regions is in contact with its respective access line of the plurality of access lines.

6. The read-only memory of claim 1, wherein the second conductive region is formed in a semiconductor below an uppermost surface of the semiconductor, wherein the plurality of access lines are formed in the semiconductor below the uppermost surface of the semiconductor and overlying the second conductive region, and wherein the plurality of first conductive regions are formed in the semiconductor overlying and in contact with the plurality of access lines and extending to the uppermost surface of the semiconductor.

7. The read-only memory of claim 1, wherein the read-only memory is configured to store a pattern of data having a first number of digits of a first data value and a second number of digits of a second data value, and wherein the number of contacts of the plurality of contacts is selected from a group consisting of the first number and the second number.

8. A method, comprising:
forming a first conductive region having a first conductivity type in a semiconductor;
forming a second conductive region having a second conductivity type different than the first conductivity type in the semiconductor overlying the first conductive region;
forming a plurality of isolation regions in the semiconductor, wherein each isolation region extends from an uppermost surface of the semiconductor to below a bottommost surface of the second conductive region;
forming a plurality of third conductive regions having the first conductivity type in the semiconductor overlying and in contact with respective portions of the second conductive region between pairs of isolation regions of the plurality of isolation regions;
forming a dielectric overlying the plurality of third conductive regions and the plurality of isolation regions;
forming a plurality of conductive contacts extending from an uppermost surface of the dielectric to respective third conductive regions of the plurality of third conductive regions; and
forming a plurality of conductors overlying the dielectric and the plurality of contacts, wherein each conductor of the plurality of conductors is connected to a respective set of contacts of the plurality of contacts.

9. The method of claim 8, wherein forming the dielectric comprises forming a second dielectric, wherein forming the plurality of conductors comprises forming a plurality of second conductors, and wherein the method further comprises:
forming a first dielectric overlying the semiconductor prior to forming the plurality of isolation regions;
forming a first conductor overlying the dielectric prior to forming the plurality of isolation regions;
forming the plurality of isolation regions through the first conductor, through the second conductor, and in the semiconductor, wherein each isolation region extends from an uppermost surface of the first conductor to below the bottommost surface of the second conductive region; and
removing the first conductor and the first dielectric from areas of the semiconductor in which the plurality of third conductive regions are to be formed prior to forming the plurality of third conductive regions.

10. The method of claim 9, wherein forming the first conductive region, forming the second conductive region, forming the first dielectric, forming the first conductor, forming the plurality of isolation regions, and forming the plurality of third conductive regions concurrently forms both a portion of an array of read-only memory cells and a portion of complementary circuitry.

11. The method of claim 8, wherein forming the plurality of conductive contacts comprises forming a number of contacts of the plurality of contacts that is less than a number of conductors of the plurality of conductors times a number of third conductive regions of the plurality of third conductive regions.

12. The method of claim 8, wherein the method is a method of forming an array of read-only memory cells having a read-only memory cell formed at each intersection of a conductor of the plurality of conductors and a third conductive region of the plurality of third conductive regions, and wherein forming the plurality of conductive contacts comprises forming a pattern of contacts of the plurality of contacts in response to a data pattern to be stored to the array of read-only memory cells, and forming the pattern of contacts of the plurality of contacts to have a number of contacts equal to a number of digits of the data pattern having a predetermined data value.

13. The method of claim 8, wherein forming the first conductive region in the semiconductor, forming the second conductive region in the semiconductor, and forming the plurality of third conductive regions in the semiconductor comprises:
forming the first conductive region below an uppermost surface of the semiconductor;
forming the second conductive region below the uppermost surface of the semiconductor and overlying the first conductive region; and
forming the plurality of third conductive regions overlying the second conductive region between pairs of isolation regions of the plurality of isolation regions and extending from the uppermost surface of the semiconductor to the second conductive region.

14. The method of claim 8, wherein forming the first conductive region having the first conductivity type comprises forming the first conductive region having a p-type conductivity, and wherein forming the second conductive region having the second conductivity type comprises forming the second conductive region having an n-type conductivity.

15. A method, comprising:
precharging a plurality of data lines of an array of read-only memory cells to a first voltage level, wherein each data line of the plurality of data lines is connected to an input of a respective latch;
applying a second voltage level different than the first voltage level to a selected access line of a plurality of access lines of the array of read-only memory cells, wherein each access line of the plurality of access lines is connected to first nodes of a respective plurality of diodes, and wherein the first nodes are selected from a group consisting of cathodes and anodes of its respective plurality of diodes; and
in response to applying the second voltage level to the selected access line, toggling an output of the respective latch of each data line of the plurality of data lines that is connected to a second node of a diode of the respective plurality of diodes for the selected access line.

16. The method of claim 15, wherein the first voltage level is higher than the second voltage level.

17. The method of claim 15, wherein the first voltage level is higher than a cut-off voltage level of the respective plurality of diodes of the selected access line and wherein the second voltage level is lower than the cut-off voltage level of the respective plurality of diodes of the selected access line.

18. The method of claim 16, wherein the first nodes are cathodes.

19. The method of claim 15, wherein precharging the plurality of data lines further sets the outputs of each respective latch to a first data value.

20. The method of claim 19, wherein toggling the output of a respective latch comprises changing its output to a second data value different than the first data value.
